(19) United States
(12) Patent Application Publication
(10) Pub. No.: US 2026/0238869 A1
(43) Pub. Date: Aug. 13, 2026

(54) OPTICAL DETECTION DEVICE, OPTICAL ELEMENT, AND ELECTRONIC APPARATUS

(71) Applicant: SONY SEMICONDUCTOR SOLUTIONS CORPORATION, KANAGAWA (JP)

(72) Inventor: YOSHIKI EBIKO, KANAGAWA (JP)

(21) Appl. No.: 19/150,631

(22) PCT Filed: Jan. 24, 2024
(86) PCT No.: PCT/JP2024/001948

§ 371 Date: Jul. 24, 2025

(30) Foreign Application Priority Data
Feb. 3, 2023 (JP) 2023-015393

(51) Int. Cl. H04N 23/55

(52) U.S. Cl. CPC H04N 23/55

(57) ABSTRACT

An optical detection device according to one embodiment of the present disclosure includes: a first light guide member including a plurality of first structures and a plurality of second structures; and a first photoelectric conversion element that photoelectrically converts light incident through the first light guide member. The first structure and the second structure include mutually different materials.

### TECHNICAL FIELD

The present disclosure relates to an optical detection device, an optical element, and an electronic apparatus.

### BACKGROUND ART

A meta surface element including silicon pillars embedded in SiO₂ is suggested (Patent Literature 1).

### CITATION LIST

### Patent Literature

Patent Literature 1: Japanese Unexamined Patent Application Publication (Published Japanese Translation of PCT Application) No. 2020-537193

### SUMMARY OF THE INVENTION

It is desirable to improve optical characteristics in a device that detects light.

It is desirable to provide an optical detection device having favorable optical characteristics.

An optical detection device according to one embodiment of the present disclosure includes: a first light guide member including a plurality of first structures and a plurality of second structures; and a first photoelectric conversion element that photoelectrically converts light incident through the first light guide member. The first structure and the second structure include mutually different materials.

An optical detection device according to one embodiment of the present disclosure includes: a lens where light is incident; a first photoelectric conversion element that photoelectrically converts the light incident through the lens; a light guide member including a plurality of structures; and a second photoelectric conversion element that photoelectrically converts light incident through the light guide member.

An optical element according to one embodiment of the present disclosure includes: a plurality of first structures; a plurality of second structures provided around the plurality of first structures; and a filling member provided between adjacent ones of the plurality of first structures and between adjacent ones of the plurality of second structures. The first structure and the second structure include mutually different materials.

An electronic apparatus according to one embodiment of the present disclosure includes: an optical system; and an optical detection device that receives light transmitted through the optical system. The optical detection device includes a first light guide member including a plurality of first structures and a plurality of second structures, and a first photoelectric conversion element that photoelectrically converts light incident through the first light guide member. The first structure and the second structure include mutually different materials.

### BRIEF DESCRIPTION OF THE DRAWINGS

FIG. 1 is a block diagram illustrating one example of a schematic configuration of an imaging device as one example of an optical detection device according to a first embodiment of the present disclosure.

FIG. 2 is a diagram illustrating one example of a pixel section of the imaging device according to the first embodiment of the present disclosure.

FIG. 3 is a diagram illustrating a configuration example of a pixel of the imaging device according to the first embodiment of the present disclosure.

FIG. 4 is a diagram illustrating one example of a plane configuration of the imaging device according to the first embodiment of the present disclosure.

FIG. 5 is a diagram illustrating one example of a cross-sectional configuration of the imaging device according to the first embodiment of the present disclosure.

FIG. 6A is a diagram illustrating a configuration example of a pixel at a different image height position of the imaging device according to the first embodiment of the present disclosure.

FIG. 6B is a diagram illustrating a configuration example of a pixel at a different image height position of the imaging device according to the first embodiment of the present disclosure.

FIG. 6C is a diagram illustrating a configuration example of a pixel at a different image height position of the imaging device according to the first embodiment of the present disclosure.

FIG. 7A is a diagram illustrating another configuration example of the pixel at the different image height position of the imaging device according to the first embodiment of the present disclosure.

FIG. 7B is a diagram illustrating another configuration example of the pixel at the different image height position of the imaging device according to the first embodiment of the present disclosure.

FIG. 7C is a diagram illustrating another configuration example of the pixel at the different image height position of the imaging device according to the first embodiment of the present disclosure.

FIG. 8 is a diagram illustrating one example of a cross-sectional configuration of an imaging device according to Modification Example 1 of the present disclosure.

FIG. 9 is a diagram illustrating another example of the cross-sectional configuration of the imaging device according to Modification Example 1 of the present disclosure.

FIG. 10 is a diagram illustrating another example of the cross-sectional configuration of the imaging device according to Modification Example 1 of the present disclosure.

FIG. 11 is a diagram illustrating one example of a plane configuration of the imaging device according to Modification Example 1 of the present disclosure.

FIG. 12A is a diagram illustrating one example of a cross-sectional configuration of an imaging device according to Modification Example 2 of the present disclosure.

FIG. 12B is a diagram illustrating another example of the cross-sectional configuration of the imaging device according to Modification Example 2 of the present disclosure.

FIG. 12C is a diagram illustrating another example of the cross-sectional configuration of the imaging device according to Modification Example 2 of the present disclosure.

FIG. 13 is a diagram illustrating one example of a cross-sectional configuration of an imaging device according to a second embodiment of the present disclosure.

FIG. 14 is a diagram illustrating another example of the cross-sectional configuration of the imaging device according to the second embodiment of the present disclosure.

FIG. 15 is a diagram illustrating one example of a cross-sectional configuration of an imaging device according to a third embodiment of the present disclosure.

FIG. 16 is a diagram illustrating another example of the cross-sectional configuration of the imaging device according to the third embodiment of the present disclosure.

FIG. 17 is a diagram illustrating one example of a cross-sectional configuration of an imaging device according to a fourth embodiment of the present disclosure.

FIG. 18 is a diagram illustrating another example of the cross-sectional configuration of the imaging device according to the fourth embodiment of the present disclosure.

FIG. 19 is a block diagram illustrating a configuration example of an electronic apparatus having an imaging device.

FIG. 20 is a block diagram depicting an example of schematic configuration of a vehicle control system.

FIG. 21 is a diagram of assistance in explaining an example of installation positions of an outside-vehicle information detecting section and an imaging section.

FIG. 22 is a view depicting an example of a schematic configuration of an endoscopic surgery system.

FIG. 23 is a block diagram depicting an example of a functional configuration of a camera head and a camera control unit (CCU).

### MODES FOR CARRYING OUT THE INVENTION

Hereinafter, embodiments of the present disclosure will be described in detail with reference to the drawings. It is to be noted that the description is given in the following order.
1. First Embodiment
2. Second Embodiment
3. Third Embodiment
4. Fourth Embodiment
5. Application Examples
6. Practical Application Examples

### 1. First Embodiment

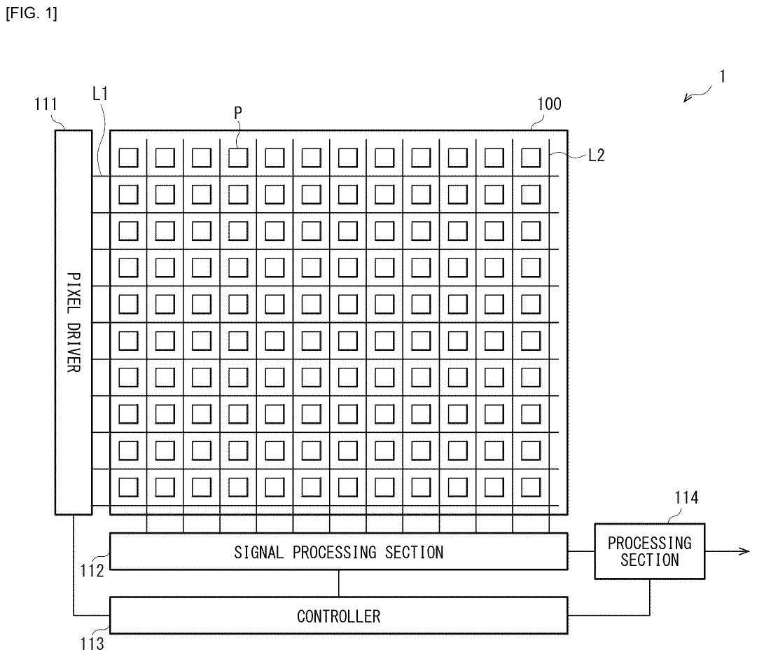

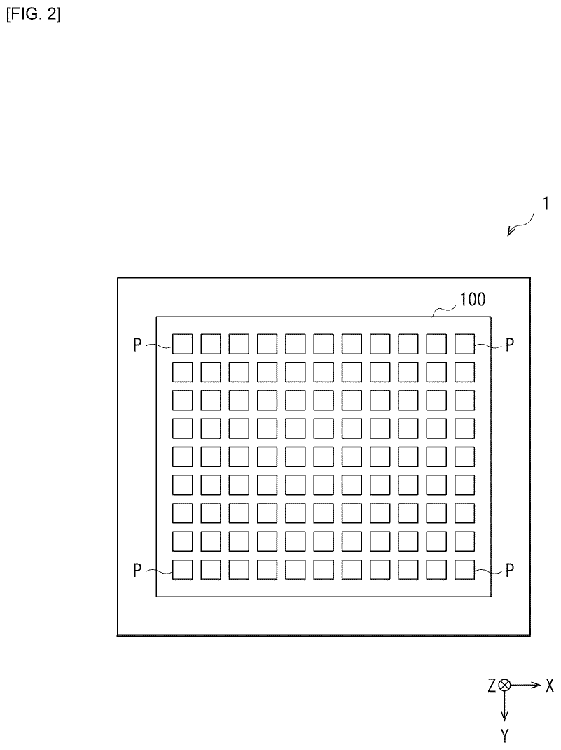

FIG. 1 is a block diagram illustrating one example of a schematic configuration of an imaging device as one example of an optical detection device according to the first embodiment of the present disclosure. FIG. 2 is a diagram illustrating one example of a pixel section of the imaging device according to the first embodiment. The optical detection device is a device that is able to detect incident light The imaging device 1 as an optical detection device has a plurality of pixels P with a photoelectric converter (photoelectric conversion element) and is configured to perform photoelectric conversion on incident light to generate a signal. The imaging device 1 is applicable to image sensors, distance measuring sensors, etc.

The imaging device 1 (optical detection device) can receive light transmitted through an optical system (not illustrated) including an optical lens and generate a signal. The photoelectric converter of each pixel P of the imaging device 1 is, for example, a photodiode (PD) and is configured to be able to perform photoelectric conversion. As in an example illustrated in FIG. 2, the imaging device 1 has, as an imaging area, a region (pixel section 100) where a plurality of pixels P is two-dimensionally disposed in a matrix form. The pixel section 100 is a pixel array where the plurality of pixels P is disposed and can be said to be a light-receiving region.

The imaging device 1 captures incident light (image light) from a subject through the optical system including the optical lens. The imaging device 1 takes an image of the subject formed by the optical lens. The imaging device 1 can photoelectrically convert the received light to generate a pixel signal. The imaging device 1 is, for example, a complementary metal oxide semiconductor (CMOS) image sensor.

The imaging device 1 as an optical detection device is a device that is able to receive incident light to generate a signal and can be said to be a light receiver. The imaging device 1 is usable to electronic apparatuses such as digital steel cameras, video cameras, portable cameras, etc. as one example.

### Schematic Configuration of Imaging Device

As in the example illustrated in FIG. 1, the imaging device 1 has, in a surrounding region of the pixel section 100 (pixel array), for example, a pixel driver 111, a signal processing section 112, a controller 113, a processing section 114, etc. Also provided in the imaging device 1 are a plurality of control lines L1 and a plurality of signal lines L2.

The control line L1 is a signal line that allows transmission of a signal controlling the pixel P and is coupled to the pixel driver 111 and the pixels P of the pixel section 100. In the example illustrated in FIG. 1, the plurality of control lines L1 is wired for each pixel row included in the plurality of pixels P arrayed in a horizontal direction (row direction) in the pixel section 100. The control line L1 is configured to transfer a control signal for signal reading from the pixel P.

The plurality of control lines L1 for each pixel row of the imaging device 1 includes: as one example, a wiring for transferring a signal controlling a transfer transistor; a wiring for transferring a signal controlling a selection transistor; a wiring for transferring a signal controlling a reset transistor; and so on. The control line L1 can be said to be a driving line (pixel driving line) for transferring signals driving the pixel P.

The signal line L2 is a signal line that is able to transmit a signal from the pixel P. and is coupled to the pixels P of the pixel section 100 and the signal processing section 112. At the pixel section 100, for example, the signal line L2 is wired for each pixel column included in the plurality of pixels P arrayed in a vertical direction (column direction). The signal line L2 is a vertical signal line and is configured to transfer signals outputted from the pixels P.

The pixel driver 111 is configured to be able to drive each pixel P of the pixel section 100. The pixel driver 111 is a driving circuit and includes a plurality of circuits including, for example, a buffer, a shift resistor, an address decoder, etc. The pixel driver 111 generates a signal for driving the pixel P and outputs the signal to each pixel P of the pixel section 100 through the control line L1. The pixel driver 111 is controlled by the controller 113 to control the pixel P of the pixel section 100.

The pixel driver 111 generates signals for controlling the pixel P, for example, a signal controlling the transfer transistor of the pixel P; a signal controlling the selection transistor; a signal controlling the reset transistor, etc. and supplies the signal to each pixel P by the control line L1. The pixel driver 111 can perform control of reading out a pixel signal from each pixel P. The pixel driver 111 can be said to be a pixel controller configured to be able to control each pixel P. Note that it is also possible to say both the pixel driver 111 and the controller 113 together as a pixel controller.

The signal processing section 112 is configured to be able to execute signal processing on a signal of a pixel inputted. The signal processing section 112 is a signal processing circuit and has, for example, a load circuit section, an analog digital (AD) converter, a horizontal selection switch, etc. Note that the signal processing section 112 may have an amplification circuit section that is configured to amplify a signal read from the pixel P through the signal line L2.

The signal selectively scanned by the pixel driver 111 and outputted from each pixel P is inputted to the signal processing section 112 through the signal line L2. The signal processing section 112 can perform signal processing, for example, AD conversion of the signal of the pixel P, a correlated double sampling (CDS), etc. The signal of each pixel P transferred through each corresponding signal line L2 is subjected to signal processing by the signal processing section 112 and outputted to the processing section 114.

The processing section 114 is configured to be able to perform signal processing on an inputted signal. The processing section 114 is a signal processing circuit and includes, for example, a circuit that performs various types of signal processing on a pixel signal. The processing section 114 may include a processor and a memory. The processing section 114 performs signal processing on a signal of a pixel inputted from the signal processing section 112 and outputs the signal of the pixel subjected to the processing. The processing section 114 can perform various types of processing, for example, noise reduction processing, gray-scale correction processing, etc.

The controller 113 is configured to be able to control various sections of the imaging device 1. The controller 113 can receive a clock provided from an outside, data for commanding an operation mode, etc., and output data such as internal information of the imaging device 1. The controller 113 is a control circuit and has, for example, a timing generator that is configured to be able to generate various types of timing signals.

The controller 113 performs driving control of the pixel driver 111, the signal processing section 112, etc. on the basis of various types of timing signals (pulse signals, clock signals, etc.) generated by the timing generator. Note that the controller 113 and the processing section 114 may be integrally configured.

The pixel driver 111, the signal processing section 112, the controller 113, the processing section 114, etc., may be provided on one semiconductor substrate or may be provided separately on a plurality of semiconductor substrates. The imaging device 1 may have a structure (stacking structure) that is configured by stacking a plurality of substrates.

### Pixel Configuration

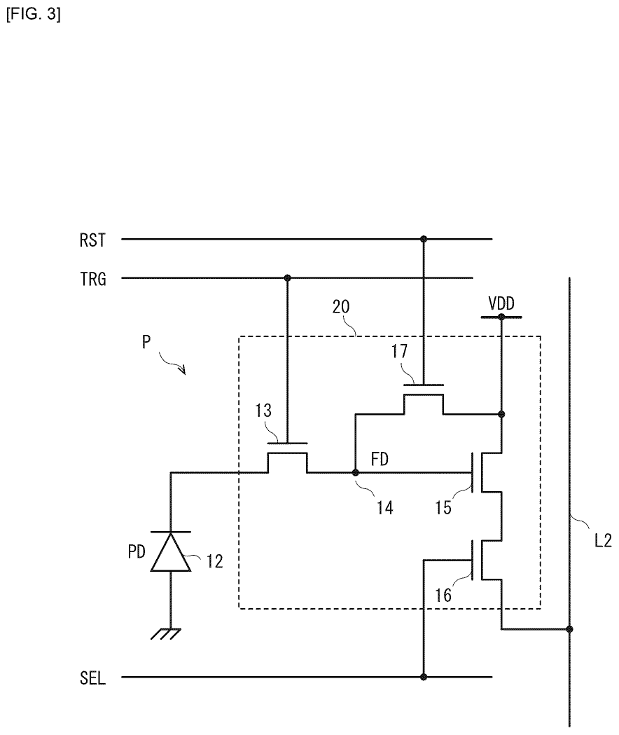

FIG. 3 is a diagram illustrating a configuration example of the pixel of the imaging device according to the first embodiment. The pixel P has a photoelectric converter 12 (a photoelectric conversion element) and a readout circuit 20. The photoelectric converter 12 is configured to receive light and generate a signal. The readout circuit 20 is configured to output a signal based on electric charges obtained through the photoelectric conversion.

The photoelectric converter 12 is a light receiver (light receiving element) and is configured to be able to generate electric charges through photoelectric conversion. In the example illustrated in FIG. 3, the photoelectric converter 12 is a photodiode (PD) and converts incident light into electric charges. The photoelectric converter 12 generates the electric charges according to an amount of light received through the photoelectric conversion.

The readout circuit 20 has, as one example, a transfer transistor 13, a floating fusion (FD) 14, an amplification transistor 15, a selection transistor 16, and a reset transistor 17. Each of the transfer transistor 13, the amplification transistor 15, the selection transistor 16, and the reset transistor 17 is a MOS transistors (MOSFET) having gate, source, and drain terminals.

In the example illustrated in FIG. 3, the transfer transistor 13, the amplification transistor 15, the selection transistor 16, and the reset transistor 17 include the respective NMOS transistors. Note that the transistors of the pixel P may include PMOS transistors.

The transfer transistor 13 is configured to be able to transfer, to the FD 14, the electric charges obtained through the photoelectric conversion performed at the photoelectric converter 12. As illustrated in FIG. 3, the transfer transistor 13 is controlled by a signal TRG and electrically couples the photoelectric converter 12 and the FD 14 or cuts the coupling of the photoelectric converter 12 and the FD 14. The transfer transistor 13 can transfer, to the FD 14, the electric charges accumulated as a result of the photoelectric conversion performed at the photoelectric converter 12.

The FD 14 is an accumulation section and is configured to be able to accumulate the transferred electric charges. The FD 14 can accumulate the electric charges obtained through the photoelectric conversion performed at the photoelectric converter 12. The FD 14 can be said to be a holding section that is able to hold the transferred electric charges. The FD 14 accumulates the transferred electric charges and converts the electric charges into a voltage according to capacity of the FD 14.

The amplification transistor 15 is configured to generate and output a signal based on the electric charges accumulated at the FD 14. As illustrated in FIG. 3, the gate of the amplification transistor 15 is electrically coupled to the FD 14 and receives input of the voltage obtained through the conversion performed at the FD 14.

The drain of the amplification transistor 15 is coupled to a power line that is supplied with a supply voltage VDD, and the source of the amplification transistor 15 is coupled to the signal line L2 via the selection transistor 16. The amplification transistor 15 can generate a signal based on the electric charges accumulated at the FD 14, that is, a signal based on the voltage of the FD 14 and output the signal to the signal line L2.

The selection transistor 16 is configured to be able to control outputting of the pixel signal. The selection transistor 16 is configured to be controlled by a signal SEL and able to output a signal from the amplification transistor 15 to the signal line L2.

The selection transistor 16 can control output timing of the pixel signal. Note that the selection transistor 16 may be provided between the power line that is supplied with the supply voltage VDD and the amplification transistor 15. Moreover, the selection transistor 16 may be omitted as needed.

The reset transistor 17 is configured to be able to reset the voltage of the FD 14. In the example illustrated in FIG. 3, the reset transistor 17 is electrically coupled to the power line that is supplied with the supply voltage VDD and is configured to reset the electric charges of the pixel P.

The reset transistor 17 is controlled by a signal RST and can reset the electric charges accumulated at the FD 14 to reset the voltage of the FD 14. Note that the reset transistor 17 can discharge, through the transfer transistor 13, the electric charges accumulated at the photoelectric converter 12.

The pixel driver 111 (see FIG. 1) supplies a control signal to gates of the transfer transistor 13, the selection transistor 16, the reset transistor 17, etc. of each pixel P through the control line L1 described above and turns the transistors into an ON state (a conducting state) or an OFF state (a non-conducting state).

The plurality of control lines L1 of the imaging device 1 includes: for example, a wiring for transferring a signal TRG controlling the transfer transistor 13; a wiring for transferring a signal SEL controlling the selection transistor 16; a wiring for transferring a signal RST controlling the reset transistor 17; etc.

Note that the readout circuit 20 may be configured to be able to change conversion efficiency (gain) at time of the conversion of the electric charges into the voltage. For example, the readout circuit 20 can have a switching transistor that is used for setting the conversion efficiency. The switching transistor is provided between the FD 14 and the reset transistor 17 as one example.

In the readout circuit 20, the switching transistor turns into an ON state, whereby the capacity added to the FD 14 of the pixel P increases, switching the conversion efficiency. The switching transistor can switch the capacitor coupled to the gate of the amplification transistor 15 and change the conversion efficiency.

The transfer transistor 13, the selection transistor 16, the reset transistor 17, the switching transistor, etc. are subjected to ON-OFF control performed by the pixel driver 111. The pixel driver 111 controls the readout circuit 20 of each pixel P, thereby causing the pixel signal from each pixel P to be outputted to the signal line L2. The pixel driver 111 can perform control of reading out the pixel signal of each pixel P to the signal line L2.

### Configuration of Imaging Device

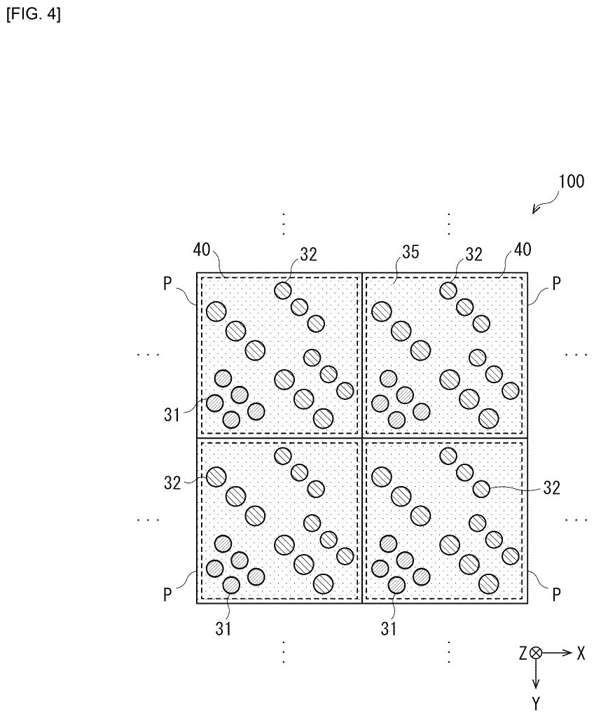

FIG. 4 is a diagram illustrating one example of a plane configuration of the imaging device according to the first embodiment. FIG. 4 illustrates a disposition example of the pixels P of the pixel section 100 in the imaging device 1. The pixels P of the imaging device 1 have a light guide section 40 (a light guide member) configured by using a plurality of structures.

The light guide section 40 has a plurality of structures and is configured to guide light from a measurement target towards the photoelectric converter. The light guide section 40 has: a plurality of kinds of structures (first structures 31 and second structures 32 in FIG. 4); and a filling member 35 provided around the structures. In the example illustrated in FIG. 4, the light guide section 40 is configured to include a plurality of first structures 31 and a plurality of second structures 32. The second structures 32 are provided around the first structures 31.

The first structure 31 and the second structure 32 are configured using different materials. The second structures 32 are disposed around the first structures 31 and have a refractive index different from a refractive index of the first structures 31. The first structures 31 and the second structures 32 have, for example, a columnar shape (a pillar-like) shape to be described later on. In the imaging device 1, the light guide section 40 is provided, for example, for each pixel P or for each plurality of pixels P, as illustrated in the example of FIG. 4.

Note that, as illustrated in FIG. 4, a direction of light incidence from a subject is a Z-axis direction, a direction orthogonal to the Z-axis direction and horizontal on a paper surface is an X-axis direction, and a direction orthogonal to the Z-axis direction and the X-axis direction and vertical on the paper surface is a Y-axis direction. In the following drawings, directions may be represented with reference to the directions of arrows in FIG. 4.

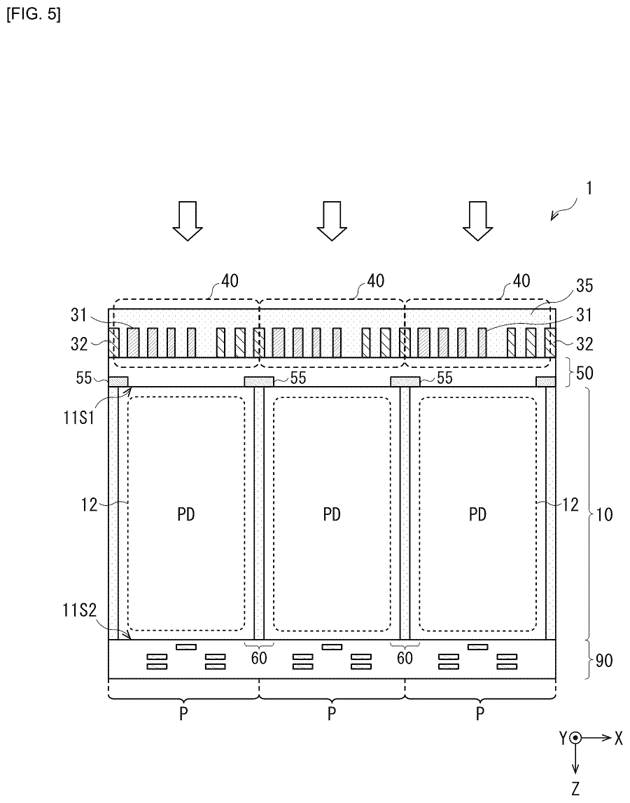

FIG. 5 is a diagram illustrating one example of a cross-sectional configuration of the imaging device according to the first embodiment. As illustrated in FIG. 5, the imaging device 1 has, for example, a configuration that the light guide section 40, an insulation layer 50, a semiconductor layer 10, and a multilayer wiring layer 90 are stacked in the Z-axis direction.

As illustrated in FIG. 5, the semiconductor layer 10 has a first surface 11S1 and a second surface 11S2 opposing each other. The second surface 11S2 is a surface opposite to the first surface 11S1. The semiconductor layer 10 includes a semiconductor substrate, for example, an Si (silicon) substrate. The first surface 11S1 of the semiconductor layer 10 is a light receiving surface (light incidence surface). The second surface 11S2 of the semiconductor layer 10 is an element formation surface where an element such as a transistor is formed. A gate electrode, a gate oxide film, etc., can be provided on the second surface 11S2 of the semiconductor layer 10.

In the example illustrated in FIG. 5, the light guide section 40, the insulation layer 50, etc., are provided on a first surface 11S1 side of the semiconductor layer 10. The multilayer wiring layer 90 is provided on a second surface 11S2 side of the semiconductor layer 10. The light guide section 40 is provided on a side where light from the optical system is incident, and the multilayer wiring layer 90 is provided on a side opposite to the light incidence side. The imaging device 1 is a so-called back-illuminated imaging device.

In the semiconductor layer 10, a plurality of photoelectric converters 12 (photoelectric conversion elements) is provided along the first surface 11S1 and the second surface 11S2 of the semiconductor layer 10. For example, the plurality of photoelectric converters 12 is embedded in the semiconductor layer 10. Note that the semiconductor layer 10 may be, for example, a silicon on insulator (SOI) substrate, a silicon germanium (SiGe) substrate, or a silicon carbide (SiC) substrate and may contain, for example, a III-V compound semiconductor material.

The multilayer wiring layer 90 includes, for example, a conductor film and an insulation film, and has a plurality of wirings, vias, etc. The multilayer wiring layer 90 includes, for example, a wiring with two or more layers. The multilayer wiring layer 90 has a configuration that a plurality of wirings is stacked with the insulation film in between. The insulation film of the multilayer wiring layer 90 can be said to be an interlayer insulation film (interlayer insulation layer).

The wiring of the multilayer wiring layer 90 is formed using a metal material such as, for example, aluminum (Al), copper (Cu), or tungsten (W). The wiring of the multilayer wiring layer 90 may be configured using polysilicon (Poly-Si) or any other conductive material. The interlayer insulation film is formed using, for example, silicon oxide (SiO), silicon nitride (SiN), or silicon oxynitride (SiON).

For example, the aforementioned readout circuit 20 (see FIG. 3) is provided at the semiconductor layer 10 and the multilayer wiring layer 90. Note that the aforementioned pixel driver 111, signal processing section 112, controller 113, processing section 114, etc., (see FIG. 1) can be provided at a substrate other than the semiconductor layer 10 or the semiconductor layer 10 and the multilayer wiring layer 90.

The insulation layer 50 is provided between a layer where the light guide section 40 is provided and the semiconductor layer 10. The insulation layer 50 is provided at the semiconductor layer 10 in a stacked manner and located on the first surface 11S1 of the semiconductor layer 10. The insulation layer 50 is formed using an insulation film such as, for example, an oxide film, a nitride film, or an oxynitride film.

The insulation layer 50 may contain, for example, silicon oxide (SiO), silicon nitride (SiN), or silicon oxynitride (SiON), or may be configured using any other insulating material. The insulation layer 50 can be said to be a flattening layer (flattening film).

A light shielding section 55 (a light shielding film) includes a member that shields light and provided at a border between adjacent ones of the plurality of pixels P. The light shielding section 55 (light shielding member) is formed, for example, inside the insulation layer 50 or on the insulation layer 50 on the first surface 11S1 side of the semiconductor layer 10. In the example illustrated in FIG. 5, the light shielding section 55 is located above a separator 60.

The light shielding section 55 contains, for example, a metal material (for example, aluminum (Al), tungsten (W), or copper (Cu)) that shields light. The light shielding section 55 may contain a material that absorbs light. The light shielding section 55 is provided around the photoelectric converter 12 and suppresses leak of light to the surrounding pixel.

Moreover, as illustrated in the example of FIG. 5, separators 60 are provided in the imaging device 1. The separator 60 is provided between adjacent ones of the plurality of photoelectric converters 12 and separates the photoelectric converters 12 from each other. The separator 60 has a trench (groove part) provided at a border between the adjacent pixels P (or photoelectric converters 12). For example, the separator 60 is provided to surround the photoelectric converters 12 in the semiconductor layer 10.

For example, as illustrated in the example of FIG. 5, the separator 60 can be provided to extend through the semiconductor layer 10. As one example, an insulation film, for example, a silicon oxide film is provided in the trench of the separator 60. Note that, for example, polysilicon or a metal material may be embedded in the trench of the separator 60.

The separator 60 may be formed using any other dielectric material with a low refractive index. For example, a void (cavity) may be provided in the trench of the separator 60. Providing the separators 60 suppresses leak of light to the surrounding pixels P. It is possible to suppress leak of unnecessary light to the surroundings and suppress, for example, occurrence of color mixture.

Note that the imaging device 1 may have a fixed charge film and an antireflection film. For example, the fixed charge film and the antireflection film are provided between the semiconductor layer 10 and the insulation layer 50. As one example, the fixed charge film contains a metal compound (such as a metal oxide or a metal nitride). The fixed charge film is, for example, a film with negative fixed electric charges and suppresses generation of a dark current at an interface of the semiconductor layer 10.

As one example, the antireflection film is configured using an insulating material such as silicon nitride (SiN) or silicon oxide (SiO). The antireflection film is provided, for example, on the first surface 11S1 side of the semiconductor layer 10 and reduces (suppresses) reflection. Note that the insulation layer 50 or the light guide section 40 may be configured to include at least one of the fixed charge film and the antireflection film.

The light guide section 40 (light guide member) has the first structures 31 and the second structures 32 and is configured to guide incident light towards the photoelectric converter 12. Light from a subject as a measurement target is incident on the light guide section 40 of each pixel P of the imaging device 1. Each of the first structures 31 and the second structures 32 is a minute (microscopic) structure of a size equal to or less than a predetermined wavelength of incident light.

The first structure 31 and the second structure 32 each have, for example, a size equal to or less than a wavelength range of infrared light. The first structure 31 and the second structure 32 may each have a size equal to or less than a wavelength range of near infrared light. Moreover, the first structure 31 and the second structure 32 may each have a size equal to or less than a wavelength range of visible light.

The light guide section 40 has: the first structures 31, the second structures 32, and the filling member 35 provided around the first structures 31 and the second structures 32. The first structure 31 and the second structure 32 are structures of, for example, a columnar (pillar-like) shape. In the light guide section 40, the second structures 32 are provided, for example, in a region around the plurality of first structures 31.

Note that the shape of the structures of the light guide section 40 is modifiable as appropriate. The first structure 31 and the second structure 32 each have, for example, a columnar shape. Moreover, the first structure 31 and the second structure 32 each can have, for example, a shape of a square prism. The shape of each of the first structure 31 and the second structure 32 may be a rectangular in plan view. The shape of the first structure 31 and the shape of the second structure 32 may be each a polygon, an oval, a cross, or any other shape.

The filling member 35 is provided to fill between adjacent ones of the plurality of first structures 31. Moreover, as illustrated in the example of FIG. 5, the filling member 35 is provided to fill between adjacent ones of the plurality of second structures 32 and between the first structure 31 and the second structure 32. The filling member 35 is embedded between the plurality of first structures 31, between the plurality of second structures 32, and between the first structure 31 and the second structure 32.

The filling member 35 may be formed to cover the first structures 31 and the second structures 32. The first structures 31 and the second structures 32 are each provided in the filling member 35 and can be said to be disposed in place of part of the filling member 35.

The light guide section 40 (light guide member) uses the first structures 31 and the second structures 32 serving as nano structures (in other words, for example, microstructures, metaatoms, nanoatoms, or nanoposts) and transmits light to the photoelectric converter 12. The light guide section 40 is an optical element (optical member) that guides (transmits) light.

The light guide section 40 can be configured as, for example, a deflection element (deflection section) that deflects light. For example, the light guide section 40 is configured to provide incident light with phase delay to deflect light. The light guide section 40 can be provided, for example, for each pixel P or each plurality of pixels P.

The first structure 31 and the second structure 32 are, for example, pillars (columnar members) as illustrated in FIG. 5. As schematically illustrated in FIG. 5, the plurality of first structures 31 and second structures 32 is disposed in a direction horizontal on the paper surface (X-axis direction) side by side with part of the filling member 35 in between.

At each pixel P of the imaging device 1, the plurality of first structures 31 and second structures 32 can be disposed at intervals equal to or less than a predetermined wavelength of the incident light, for example, equal to or less than a wavelength of infrared light (or visible light). In the imaging device 1, as one example, the plurality of first structures 31 and the plurality of second structures 32 can be provided at intervals equal to or less than a wavelength range of near infrared light in the X-axis direction and the Y-axis direction.

The first structure 31 has a refractive index different from a refractive index of an adjacent medium. In the example illustrated in FIG. 5, the first structure 31 has the refractive index different from the refractive index of the filling member 35 arranged around the first structures 31. Moreover, the second structure 32 has a refractive index different from a refractive index of an adjacent medium. In the example illustrated in FIG. 5, the second structure 32 has the refractive index different from the refractive index of the filling member 35 arranged around the second structures 32.

In the present embodiment, the first structure 31 and the second structure 32 are configured using different materials. The second structure 32 has the refractive index different from the refractive index of the first structure 31. The first structure 31 of the light guide section 40 may have, for example, a higher refractive index than the filling member 35. Moreover, the first structure 31 may also have a higher refractive index than the second structure 32. The first structure 31 can contain a material that has a higher refractive index than the filling member 35 and the second structure 32.

The second structure 32 of the light guide section 40 may have a lower refractive index than the filling member 35. Moreover, the second structure 32 may also have a lower refractive index than the first structure 31. The second structure 32 may contain a material that has a lower refractive index than the filling member 35 and the first structure 31.

The first structure 31 and the second structure 32 of the light guide section 40 may be configured using an inorganic material or may be configured using an organic material. The first structure 31 and the second structure 32 are configured using different materials. The first structure 31 can be configured using, as one example, amorphous silicon (a-Si). The first structure 31 may be configured using, for example, polysilicon (Poly-Si) or germanium (Ge).

Moreover, the first structure 31 may contain, for example, a simple substance such as titanium, hafnium, zirconium, tantalum, aluminum, niobium, or indium, oxide, nitride, oxynitride, or a composite thereof. For example, the first structure 31 can contain a metal compound (such as metal oxide or metal nitride) such as titanium oxide (TiO). The first structure 31 may be configured using an organic material.

The second structure 32 can be configured using magnesium fluoride (MgF) as one example. The second structure 32 may be formed using silicon oxide, silicon nitride, silicon oxynitride, silicon carbide, silicon carbide oxide, or any other silicon compound. Moreover, the second structure 32 may also be configured from an organic substance such as siloxane. The second structure 32 may be configured using, for example, any of siloxane-based resin, styrene-based resin, acrylic resin, etc.

The filling member 35 is formed using an organic material such as oxide, nitride, or oxynitride as one example. The filling member 35 contains, for example, any of silicon oxide, silicon nitride, silicon oxynitride, silicon carbide, silicon carbide oxide, etc. Note that the filling member 35 may be configured using an organic material.

The filling member 35 may be configured using, for example, siloxane-based resin, styrene-based resin, or acrylic resin. The filling member 35 may contain a material containing fluorine in any of the aforementioned types of resin. The filling member 35 may also be formed using a material with a bead that has a higher refractive index than any of the aforementioned types of resin and is filled in any of the aforementioned types of resin.

Materials of the first structure 31, the second structure 32, and the filling member 35 can be selected in accordance with a difference in a refractive index from a refractive index of the surrounding medium and a wavelength range of incident light as a measurement target. For example, in a case of the imaging device 1 that guides infrared light, the first structure 31 may contain, for example, amorphous silicon or germanium. Moreover, for example, in a case of the imaging device 1 that guides visible light, the first structure 31 may be configured using titanium oxide.

The light guide section 40 is able to cause a phase delay in the incident light due to the refractive index difference between the first structure 31 and the second structure 32 and the surrounding medium, thereby having an influence on a wave surface. For example, the light guide section 40 is able to provide the incident light with a phase delay with the first structure 31, the second structure 32, and the filling member 35 and thereby adjust a light transmission direction.

Materials (optical constants of the respective materials), sizes, shapes, pitches (disposition intervals), etc. of the plurality of first structures 31 and second structures 32 are defined to allow light in a given wavelength range included in the incident light to travel in a desired direction. In the example illustrated in FIG. 5, the refractive index, the size (width, height, etc.), the shape, and the pitch of each of the first structure 31 and the second structure 32 of the light guide section 40, the refractive index of the filling member 35, etc. can be set.

The light guide section 40 is an optical element that uses a metamaterial (meta surface) technology and can be said to be a light guide element that is able to guide light. The light guide section 40 can be configured as, for example, an optical element (deflector) that changes a travel direction of light in a specific wavelength range.

It is possible to adjust a direction of light transmitted by the light guide section 40 using the materials of the first structure 31, the second structure 32, the filling member 35, etc. and the shapes, heights, disposition positions, etc. of the first structure 31 and the second structure 32. For example, the materials, sizes, etc. of the first structure 31, the second structure 32, etc. are defined to focus, on the photoelectric converter 12, light (for example, infrared light) in a wavelength band as a detection target.

Light from the subject is incident on the photoelectric converter 12 of each pixel P of the imaging device 1 through the light guide section 40, as described above. The photoelectric converter 12 of each pixel P can receive the light incident through the first structure 31 and the second structure 32 of the light guide section 40 and perform photoelectric conversion thereon to generate electric charges according to an amount of light received. Thus, the imaging device 1 can generate a pixel signal obtained through the photoelectric conversion performed by the photoelectric converter 12.

Using image data (an image signal) including the pixel signal of each pixel makes it possible to generate, for example, an infrared image, a visible image, etc. In the imaging device 1 according to the present embodiment, it is possible to appropriately guide light by the light guide section 40 and suppress deterioration in sensitivity to incident light.

In the present embodiment, as described above, the light guide section 40 is configured using the first structures 31 and the second structures 32. The first structure 31 and the second structure 32 include the mutually different materials. Configuring the light guide section 40 with the first structures 31 and the second structures 32 including the mutually different materials makes it possible to realize a desired amount of phase delay.

It is possible to make fine adjustment of a phase difference of light in accordance with the refractive index of each of the first structure 31, the second structure 32, and the filling member 35 and appropriately guide incident light. This therefore makes it possible to efficiently focus light on the photoelectric converter 12, allowing an improvement in the sensitivity to incident light.

As described above, with the imaging device 1 according to the present embodiment, it is possible to dispose a plurality of types of structures (for example, the first structures 31 and the second structures 32) using two or more types of materials to thereby improve light control performance. It is possible to improve optical performance of the imaging device 1 while avoiding an increase in the number of processes in manufacturing processes. It is possible to suppress an increase in manufacturing costs of the imaging device 1.

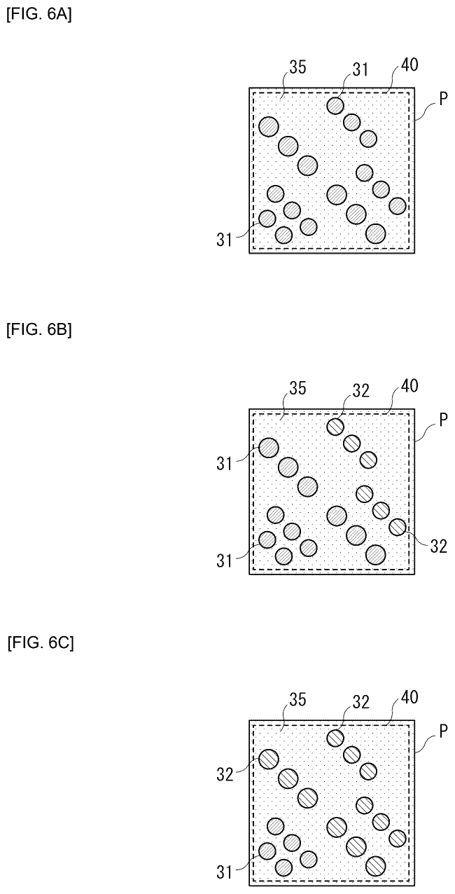

FIGS. 6A to 6C are diagrams illustrating configuration examples of pixels at different image height positions of the imaging device according to the first embodiment. FIG. 6A schematically illustrates one example of a plane configuration of the pixel in a region near a center of the pixel section 100 (pixel array) of the imaging device 1, that is, a region where a distance from the center of the pixel section 100 (that is, the image height) is substantially zero. FIG. 6B illustrates one example of a plane configuration of the pixel in a region at the higher image height than the image height in FIG. 6A. FIG. 6C illustrates one example of a plane configuration of the pixel in a region at the higher image height than the image height in FIG. 6B.

Light from the optical lens is incident substantially vertically to a central portion of the pixel section 100 (pixel array) of the imaging device 1. On the other hand, light is incident diagonally in a peripheral portion located on an outer side than the central portion, that is, a region separated from the center of the pixel section 100. Thus, in the imaging device 1, the light guide section 40 in each pixel P may be configured in a different manner depending on a distance from the pixel section 100, that is, an image height, as illustrated in the examples of FIGS. 6A to 6C.

As one example, the light guide section 40 of the pixel P has either of the first structures 31 and the second structures 32, for example, the first structure 31 in the region near the center of the pixel section 100, as illustrated in FIG. 6A. The light guide section 40 of the pixel P has the first structures 31 and the second structures 32 in the regions at the high image heights, as illustrated in FIGS. 6B and 6C.

As illustrated in FIG. 6C, a larger number of second structures 32 than a number of the second structures 32 in FIG. 6B may be disposed in the region at the higher image height than the image height in FIG. 6B. Each pixel P of the imaging device 1 may be configured to have pillar density with a lower refractive index (or a higher refractive index) continuously changing towards the center of the image height. For example, the number of each of the first structures 31 and the second structures 32 at each pixel P can be configured to vary depending on the image height.

As described above, the imaging device 1 is configured to have the light guide section 40 of each pixel P varying in accordance with the image height, and is able to appropriately perform pupil correction. It is possible to suppress a decrease in an amount of light incident on the photoelectric converter 12 and prevent deterioration in the sensitivity to incident light. It is possible to appropriately transmit the incident light to the photoelectric converter 12 even upon oblique light incidence.

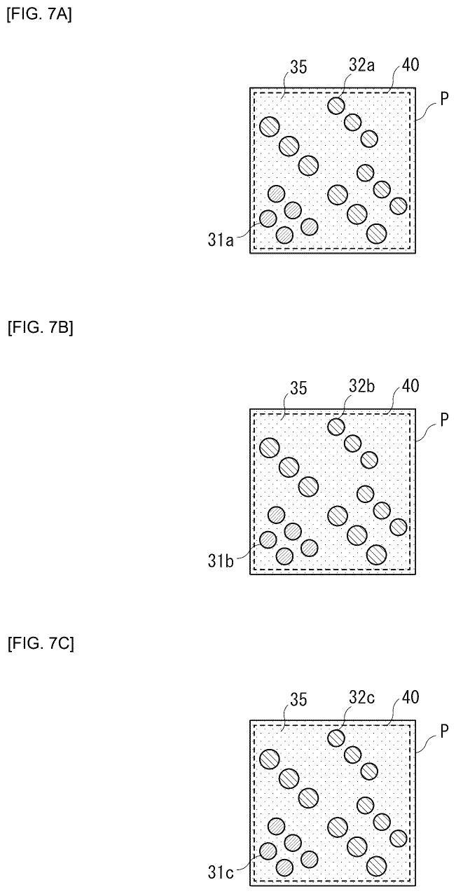

FIGS. 7A to 7C are diagrams illustrating other configuration examples of the pixels of the imaging device at different image heights. FIG. 7B illustrates the configuration example of the pixel in a region at the higher image height than the image height in FIG. 7A, and FIG. 7C illustrates the configuration example of the pixel in a region at the higher image height than the image height in FIG. 7B.

The imaging device 1 may have a light guide section 40 provided with structures with different refractive indices according to the image heights. For example, first structures 31a to first structures 31c illustrated in FIGS. 7A to 7C may be respectively configured using different materials. Moreover, second structures 32a to second structures 32c may be respectively configured using different materials.

As illustrated in FIG. 7A, the light guide section 40 of the pixel P has the first structures 31a and the second structures 32a in a region near the center of the pixel section 100. As illustrated in FIG. 7B, the light guide section 40 of the pixel P has, for example, the first structures 31b that have a higher refractive index than the first structures 31a in a region at the higher image height than the image heigh in FIG. 7A. Moreover, the light guide section 40 of the pixel P may have second structures 32b that have a higher refractive index than the second structures 32a.

As illustrated in FIG. 7C, the light guide section 40 of the pixel P has, for example, the first structures 31c that have a higher refractive index than the first structures 31b in a region at the higher image height than the image height in FIG. 7B. Moreover, the light guide section 40 of the pixel P may have the second structures 32c that have a higher refractive index than the second structures 32b.

As described above, the structures with the different refractive indices according to the image heights (the first structures 31a to 31c and the second structures 32a to 32c in FIGS. 7A to 7C) may be provided in the imaging device 1. This makes it possible to guide incident light to the photoelectric converter 12 even upon oblique light incidence. It is possible to suppress deterioration in the optical performance of the imaging device 1 for oblique incident light.

### Workings and Effects

The optical detection device according to the present embodiment includes: a first light guide member (the light guide section 40) that includes a plurality of first structures (the first structures 31) and a plurality of second structures (the second structures 32); and a first photoelectric conversion element (the photoelectric converter 12) that photoelectrically converts light incident through the first light guide member. The first structures and the second structures include mutually different materials.

In the optical detection device (imaging device 1) according to the present embodiment, the light guide section 40 having the first structures 31 and the second structures 32 is provided. The first structures 31 and the second structures 32 include the mutually different materials. Consequently, it is possible to appropriately guide incident light to the photoelectric converter 12. It is possible to realize an optical detection device having favorable optical performance.

The optical element according to the present embodiment includes: the plurality of first structures (first structures 31) and the plurality of second structures (second structures 32) provided around the plurality of first structures 31; a filling member (the filling member 35) provided between adjacent ones of the plurality of first structures and between adjacent ones of the plurality of second structures. The first structures and the second structures include mutually different materials.

The optical element (the light guide section 40) according to the present embodiment has the first structures 31, the second structures 32, and the filling member 35. The first structures 31 and the second structures 32 include the mutually different materials. Consequently, it is possible to appropriately focus incident light. It is possible to realize an optical element having favorable optical characteristics.

### 1-1. Modification Example 1

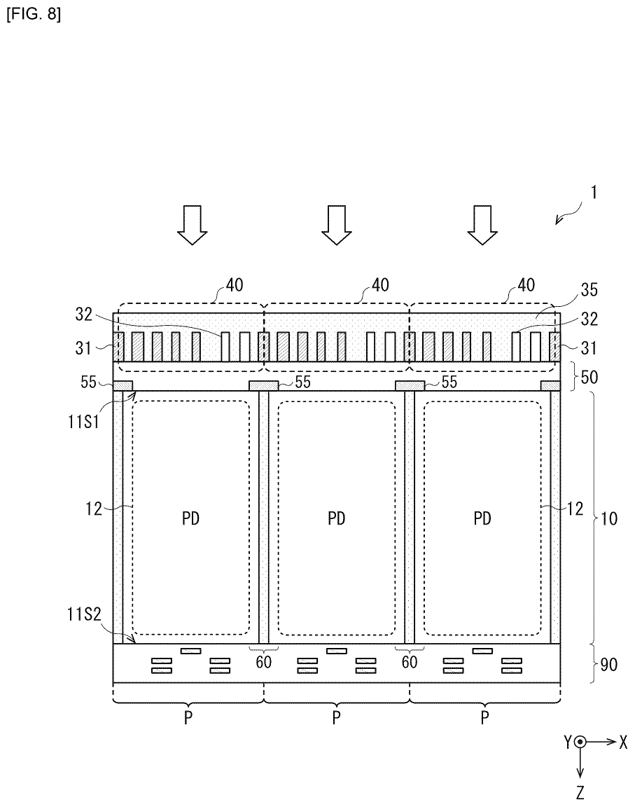

FIG. 8 is a diagram illustrating one example of a cross-sectional configuration of an imaging device according to Modification Example 1 of the present disclosure. Second structures 32 of a light guide section 40 may be configured using air (void). In the example illustrated in FIG. 8, the second structure 32 has the space (void). It is possible to appropriately guide light by providing incident light with a phase delay due to a refractive index difference between the second structure 32 as a member with a low refractive index and a medium around the second structure 32.

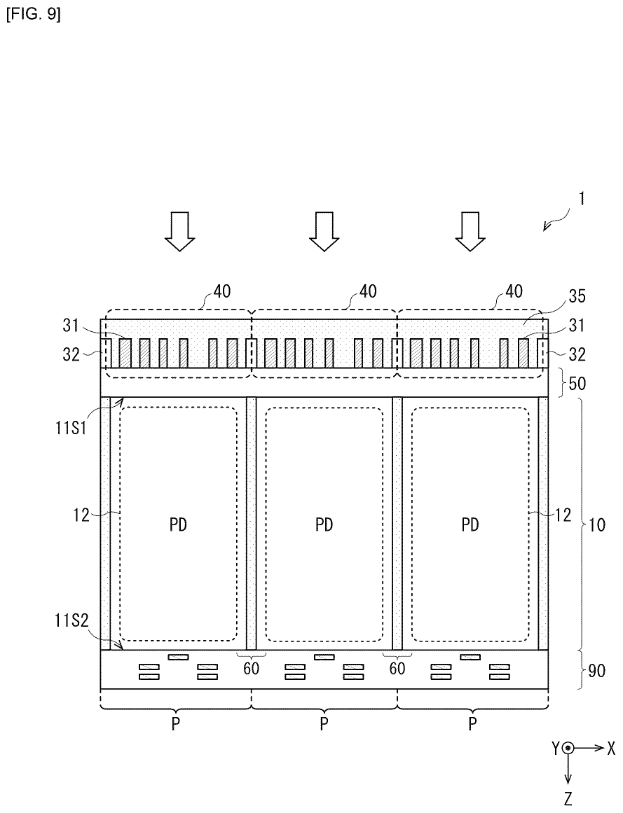

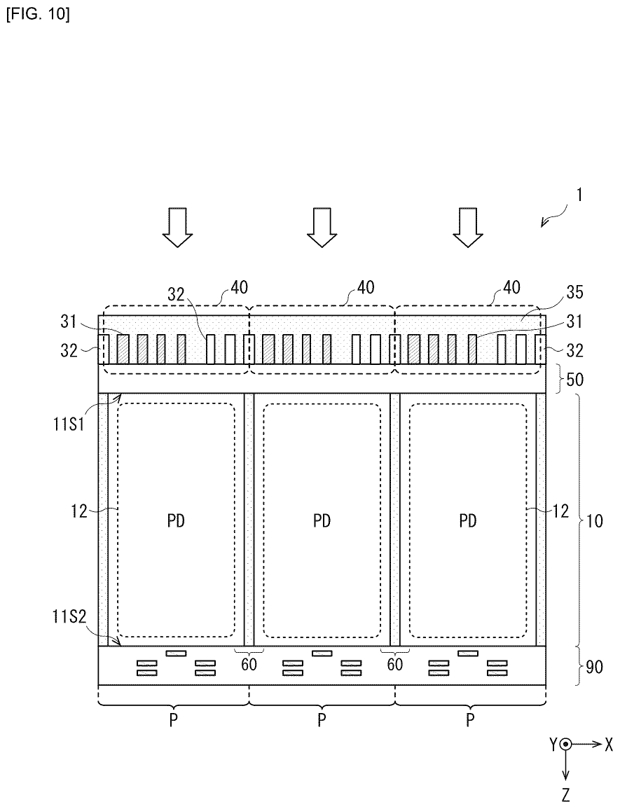

FIGS. 9 and 10 are diagrams illustrating other examples of the cross-sectional configuration of the imaging device according to Modification Example 1. As in the example of FIG. 9, second structure 32 configured using air may be provided at a border between adjacent ones of the plurality of pixels P. At least a part of the second structures 32 with the void is provided at the border between adjacent ones of the plurality of pixels P.

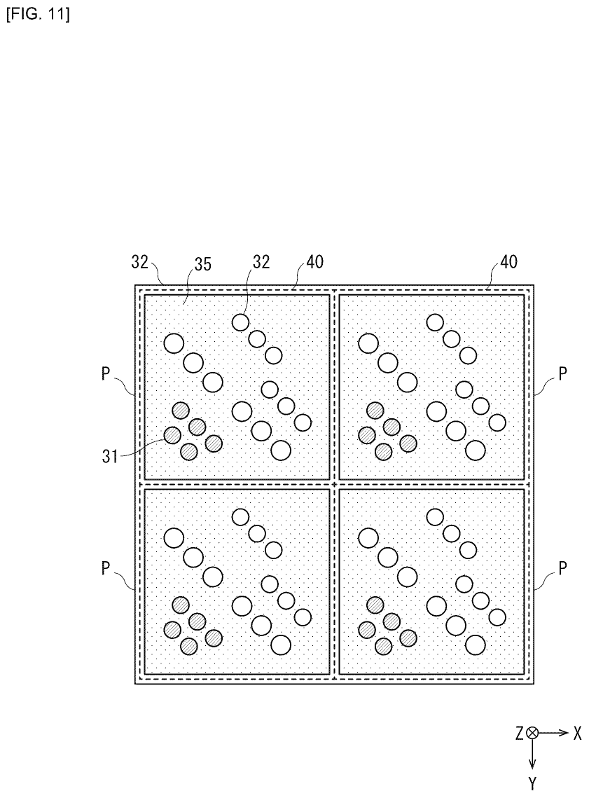

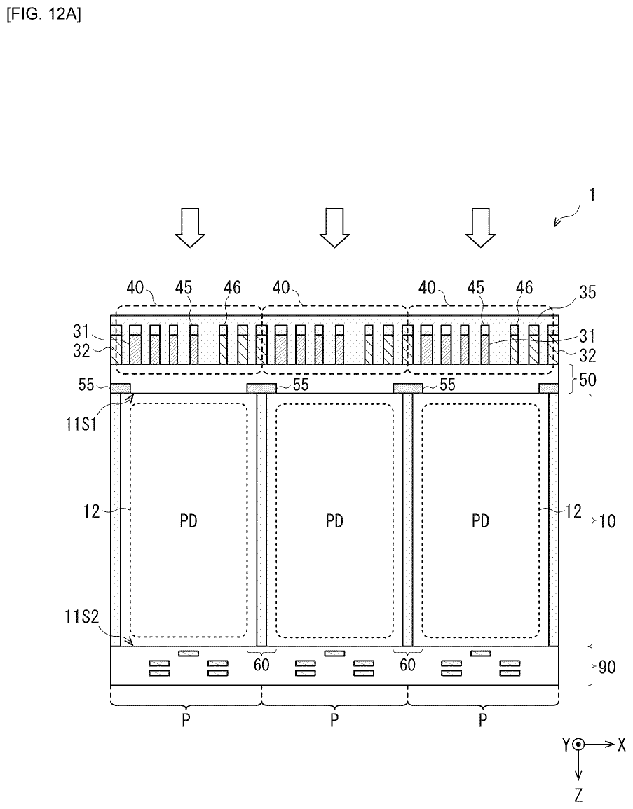

As in the example illustrated in FIG. 10, the second structures 32 may be provided around first structures 31 and at the border between adjacent ones of the plurality of pixels P. As schematically lustrated in FIG. 11, the second structure 32 may contain the air (void) and formed to extend along the border between the pixels P in plan view. For example, the second structure 32 having a columnar shape and the second structure 32 provided along the border between the plurality of pixels P are disposed at each pixel P. Note that, as illustrated in FIG. 9 or FIG. 10, the imaging device 1 may have no light shielding section 55. In other words, the second structure 32 located above (immediately above) a separator 60 may contain the air.

In the present modification example, providing the second structure 32 with the void at the border between adjacent ones of the plurality of pixels P makes it possible to suppress light leakage to the surrounding pixels P. It is possible to suppress leakage of unnecessary light and suppress mixture of noise with a pixel signal. Moreover, even with the present modification example, it is possible to provide similar effects as the effects provided by the embodiment described above.

### 1-2. Modification Example 2

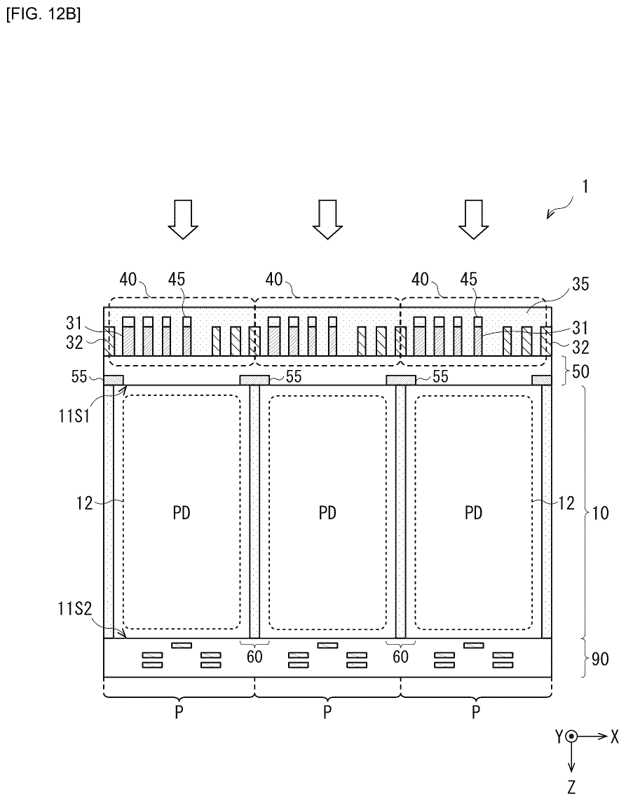

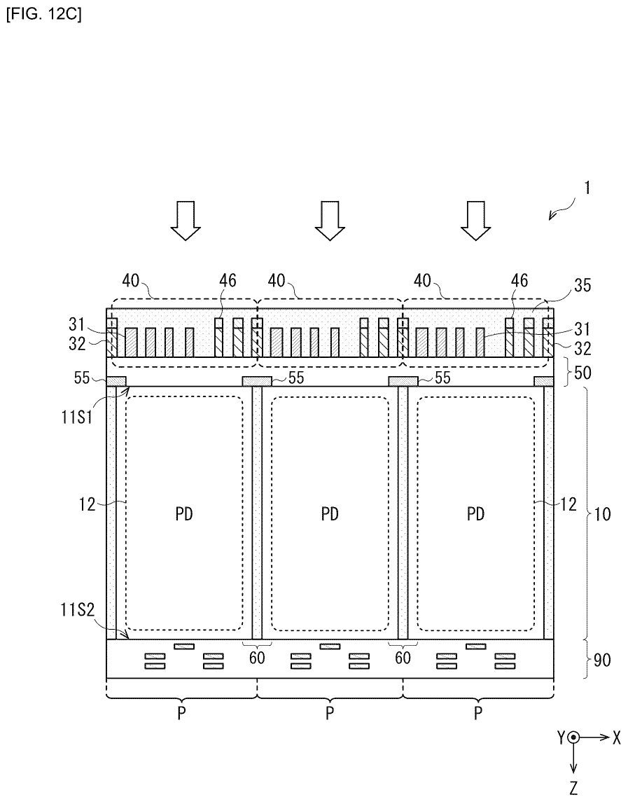

FIGS. 12A to 12C are diagrams each illustrating one example of a cross-sectional configuration of an imaging device according to Modification Example 2 of the present disclosure. An antireflection film may be provided for structures of a light guide section 40 in the imaging device 1. In the example illustrated in FIG. 12A, the light guide section 40 of each pixel P has antireflection films 45 and antireflection films 46.

The antireflection film 45 is provided for the first structure 31 and has a refractive index different from a refractive index of the first structure 31. The antireflection film 45 has, for example, a lower refractive index than the first structure 31. The antireflection film 45 is provided at the first structure 31 and reduces (suppresses) reflection.

The antireflection film 46 is provided for the second structure 32 and has a refractive index different from a refractive index of the second structure 32. The antireflection film 46 has, for example, a lower refractive index than the second structure 32. The antireflection film 46 is provided on the second structure 32 and reduces reflection.

The antireflection film 45 and the antireflection film 46 are each configured using an insulating material such as, for example, silicon oxide (SiO) or silicon nitride (SiN). The antireflection film 45 and the antireflection film 46 may be configured using another material.

Note that the light guide section 40 may be configured to have only either of the antireflection films 45 and the antireflection films 46, as illustrated in FIG. 12B and FIG. 12C. For example, in a case where the second structure 32 includes a void, the antireflection film 46 may not be disposed on the second structure 32.

### 2. Second Embodiment

Next, the second embodiment of the present disclosure will be described. Hereinafter, similar components as the components of the embodiment described above will be provided with the same signs, a description of which will be omitted as appropriate.

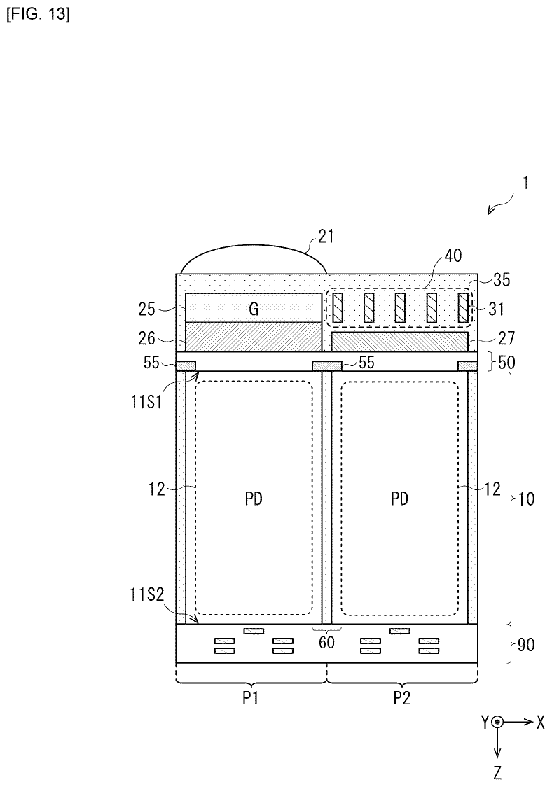

FIG. 13 is a diagram illustrating one example of a cross-sectional configuration of an imaging device according to the second embodiment. A plurality of pixels P of a pixel section 100 of the imaging device 1 includes a plurality of pixels P1 and pixels P2. The pixel P1 has a filter 25 and a filter 26, as illustrated in FIG. 13. The filter 25 is, for example, an RGB color filter. The filter 26 is a filter (IR-cut filter) that shields infrared light. The pixel P1 is a pixel having a photoelectric converter 12 that receives visible light and perform photoelectric conversion thereon.

The plurality of pixels P1 provided at the pixel section 100 of the imaging device 1 includes: for example, a plurality of pixels (pixels R) provided with a filter 25 that transmits red (R) light; a plurality of pixels (pixels G) provided with a filter 25 that transmits green (G) light; and a plurality of pixels (pixels B) provided with a filter 25 that transmits blue (B) light.

The filter 25 provided at the pixel P1 of the pixel section 100 is not limited to a color filter for primary colors (RGB), and may be a color filter for complementary colors, for example, Cy (cyan), Mg (magenta), Ye (yellow), etc. A filter for W (white), that is, a filter that transmits light in a full wavelength range of incident light may be disposed.

The pixel P2 is, for example, a pixel (IR pixel) having a filter 27 that transmits infrared light. The filter 27 is configured by, as one example, stacking a B (blue) color filter and a R (red) color filter. The pixel P2 is a pixel having a photoelectric converter 12 that receives infrared light and performs photoelectric conversion thereon.

In the example illustrated in FIG. 13, a lens 21 is provided for the pixel P1, and a light guide section 40 is provided for the pixel P2. The lens 21 is an optical member called an on-chip lens. The lens 21 (lens part) is provided above the filter 25 for each pixel P1 or each plurality of pixels P1. Light from a subject is incident on the lens 21 through an optical system such as an imaging lens.

In the example illustrated in FIG. 13, a height of the lens 21 in an arrow Z direction, that is, a thickness of the lens 21 in the arrow Z direction is set to focus, on the photoelectric converter 12 of the pixel P1, light in a wavelength range of visible light incident on the lens 21. The photoelectric converter 12 of the pixel P1 photoelectrically converts light incident through the lens 21.

Moreover, a refractive index, size, pitch, etc. of a first structure 31 of the light guide section 40 of the pixel P2 is set to focus, on the photoelectric converter 12 of the pixel P2, light in a wavelength range of incident infrared light. Note that the light guide section 40 may be configured using a plurality of types of structures (for example, first structures 31 and second structures 32), as is the case with the first embodiment.

As described above, it is possible to appropriately guide visible light by the lens 21 at the pixel P1 of the imaging device 1. Moreover, it is also possible to appropriately guide infrared light with the light guide section 40 at the pixel P2 of the imaging device 1. It is possible to generate an infrared image (IR image) and a visible image by use of a pixel signal of each pixel obtained by the plurality of pixels P1 and pixels P2 of the imaging device 1. It is possible to appropriately set a focus point at the pixel P1 serving as a RGB pixel and at the pixel P2 serving as an IR pixel, allowing an improvement in image quality.

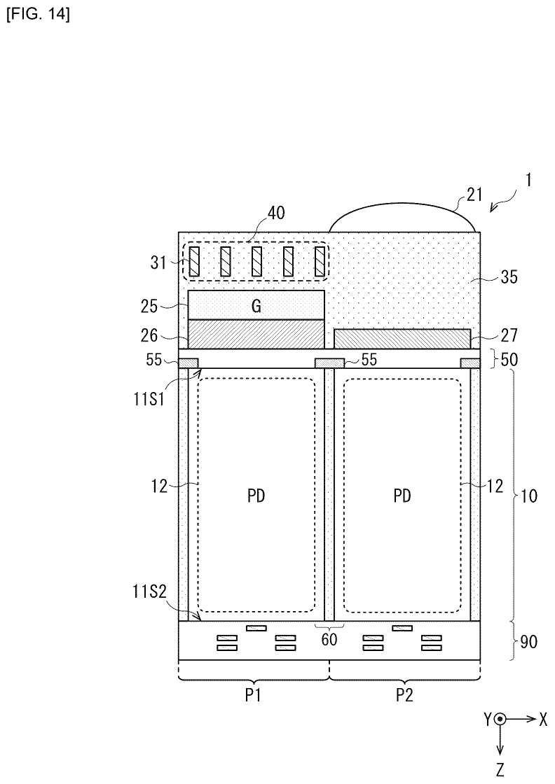

Note that the light guide section 40 may be disposed for the pixel P1 and the lens 21 may be disposed for the pixel P2, as in the example illustrated in FIG. 14. In the aforementioned case, the refractive index, size, etc. of the first structure 31 of the light guide section 40 of the pixel P1 can be set to focus incident visible light on the photoelectric converter 12 of the pixel P1. Moreover, the height (thickness) of the lens 21 in the Z-axis direction can be set to focus, on the photoelectric converter 12 of the pixel P2, infrared light incident on the lens 21.

This makes it possible to appropriately guide visible light by the light guide section 40 at the pixel P1 of the imaging device 1. It is also possible to appropriately guide infrared light by the lens 21 at the pixel P2 of the imaging device 1. It is possible to appropriately adjust a focus point at the pixel P1 and the pixel P2, allowing an improvement in image quality of an image.

### Workings and Effects

The optical detection device according to the present embodiment includes: a lens (the lens 21) where light is incident; a first photoelectric conversion element (for example, the photoelectric converter 12 of the pixel P1) that photoelectrically converts light incident through the lens; a light guide member (the light guide section 40) that includes a plurality of structures; and a second photoelectric conversion element (for example, the photoelectric converter 12 of the pixel P2) that photoelectrically converts light incident through the light guide member.

Provided in the optical detection device (imaging device 1) according to the present embodiment are: for example, the pixels P1 having the photoelectric converter 12 that photoelectrically converts light incident through the lens 21 and the pixels P2 that photoelectrically converts light incident through the light guide section 40. This therefore makes it possible to appropriately guide the incident light by the lens 21 at the pixel P1 and appropriately guide incident light by the light guide section 40 at the pixel P2. It is possible to realize an optical detection device having favorable optical characteristics.

### 3. Third Embodiment

Next, the third embodiment of the present disclosure will be described. Hereinafter, components same as the components of the embodiments described above will be provided with the same signs, a description of which will be omitted as appropriate.

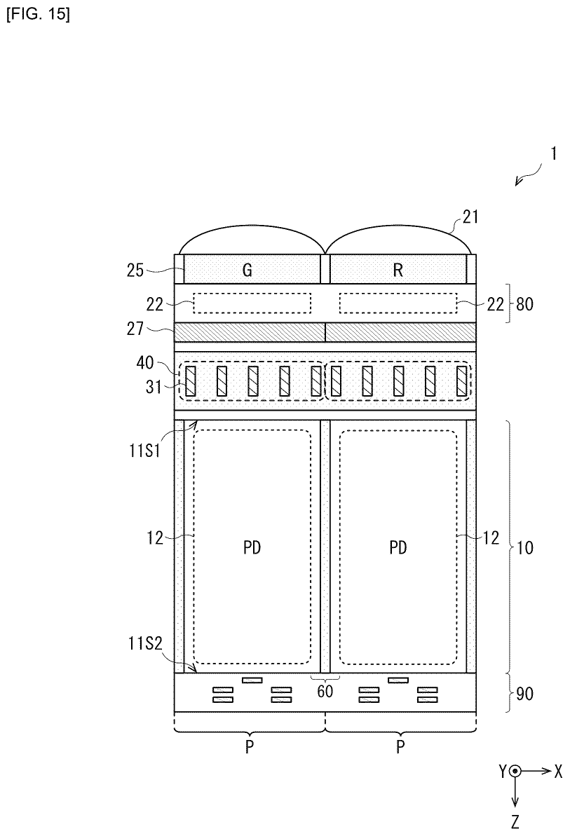

FIG. 15 is a diagram illustrating one example of a cross-sectional configuration of an imaging device according to the third embodiment. As illustrated in FIG. 15, a pixel P of the imaging device 1 has a lens 21, a filter 25, a photoelectric converter 22, a filter 27, a light guide section 40, and a photoelectric converter 12. The filter 25 is, for example, an RGB color filter. The filter 27 is configured to transmit infrared light.

As in the example illustrated in FIG. 15, provided are: from a light incidence side, the lens 21, the filter 25, the photoelectric converter 22, the filter 27, the light guide section 40, and the photoelectric converter 12. The photoelectric converter (photoelectric conversion element) 22 is configured to receive light and generate a signal. The photoelectric converter 22 is a light receiver (light receiving element) and is configured to be able to generate electric charges through photoelectric conversion.

The photoelectric converter 22 is, for example, a photodiode (PD) and converts incident light into electric charges. The photoelectric converter 22 is configured using an inorganic material such as, for example, silicon. In the example illustrated in FIG. 15, the photoelectric converter 22 is provided at a semiconductor layer 80. A plurality of photoelectric converters 22 is formed at the semiconductor layer 80. Note that the photoelectric converter 22 may be configured using an organic material. A photoelectric conversion film including an organic material may be provided as the photoelectric converter 22.

In the example illustrated in FIG. 15, a height of the lens 21 in a Z-axis direction, that is, a thickness of the lens 21 in the Z-axis direction is adjusted to focus, on the photoelectric converter 22, light in a wavelength range of visible light incident on the lens 21. The photoelectric converter 22 can photoelectrically convert visible light incident through the lens 21 and the filter 25 to generate a pixel signal.

Moreover, in the example illustrated in FIG. 15, a refractive index, size, pitch, etc. of a first structure 31 of the light guide section 40 is set to focus, on the photoelectric converter 12, light in a wavelength range of incident infrared light. The photoelectric converter 12 can photoelectrically convert infrared light incident through the lens 21, the filter 25, the photoelectric converter 22, the filter 27, and the light guide section 40 to generate a pixel signal. Note that the light guide section 40 may be configured using a plurality of types of structures (for example, the first structures 31 and second structures 32), as is the case with the first embodiment.

In the present embodiment, it is possible to guide visible light to the photoelectric converter 22 by the lens 21 and focus, on the photoelectric converter 12, infrared light by the light guide section 40. It is possible to generate an infrared image (for example, an NIR image) and a visible image by using a pixel signal of each pixel P of the imaging device 1. It is possible to appropriately adjust a focus point for each of the visible light and the infrared light, allowing an improvement in image quality.

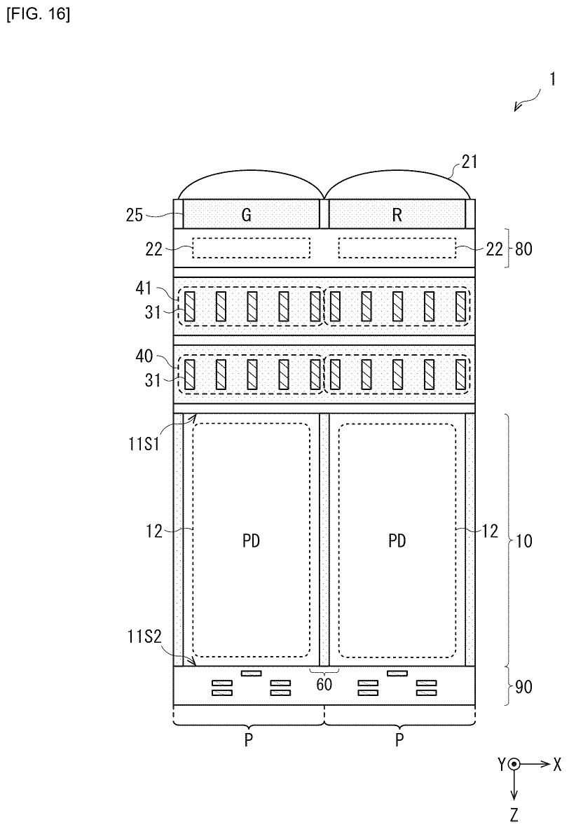

Note that the imaging device 1 may have, instead of or in addition to the filter 27 that transmits infrared light, a light guide section 41, as in the example illustrated in FIG. 16. The light guide section 41 is configured to transmit, for example, light in a specific wavelength range (for example, light in a wavelength range of infrared light).

The light guide section 41 is configured using, as one example, the first structures 31 and the second structures 32 having a columnar shape, etc., as is the case with the light guide section 40. The structures (For example, the first structures 31 and the second structures 32) of each of the light guide section 40 and the light guide section 41 can be formed with, for example, different materials, sizes, shapes, etc.

### Workings and Effects

The optical detection device according to the present embodiment includes: a lens (the lens 21) where light is incident; a first photoelectric conversion element (for example, the photoelectric converter 22) that photoelectrically converts light incident through the lens; a light guide member (for example, the light guide section 40) that includes a plurality of structures; and a second photoelectric conversion element (for example, the photoelectric converter 12) that photoelectrically converts light incident through the light guide member. Provided are: from the light incidence side, the lens, the first photoelectric conversion element, the light guide member, and the second photoelectric conversion element.

In the optical detection device (the imaging device 1) according to the present embodiment, the pixel P has: for example, the photoelectric converter 22 that photoelectrically converts light incident through the lens 21; and the photoelectric converter 12 that photoelectrically converts light incident through the light guide section 40. In the pixel P, for example, it is possible to appropriately focus, on the photoelectric converter 12, visible light by the lens 21 and appropriately focus, on the photoelectric converter 12, infrared light by the light guide section 40. It is possible to realize an optical detection device having favorable optical characteristics.

### 4. Fourth Embodiment

Next, the fourth embodiment of the present disclosure will be described. Hereinafter, components similar to the components of the embodiments described above will be provided with the same signs, a description of which will be omitted as appropriate.

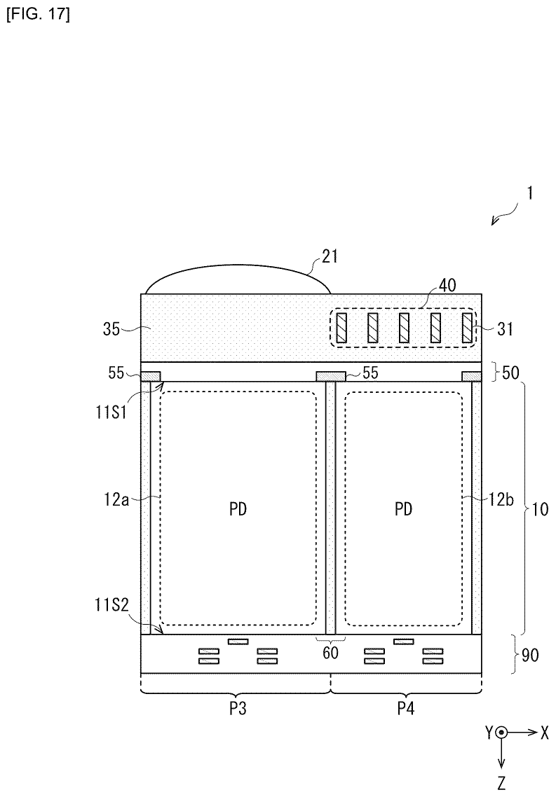

FIG. 17 is a diagram illustrating one example of a cross-sectional configuration of an imaging device according to the fourth embodiment. A plurality of pixels P of a pixel section 100 of the imaging device 1 includes a plurality of pixels P3 and pixels P4. A photoelectric converter 12a of the pixel P3 and a photoelectric converter 12b of the pixel P4 have mutually different sizes. The photoelectric converter 12a of the pixel P3 and the photoelectric converter 12b of the pixel P4 have mutually different sensitivities to incident light.

In the example illustrated in FIG. 17, the photoelectric converter 12a of the pixel P3 has a larger light receiving area than the photoelectric converter 12b of the pixel P4, and thus an amount of light received at the photoelectric converter 12a is larger than an amount of light received at the photoelectric converter 12b. The pixel P3 has higher sensitivity than the pixel P4.

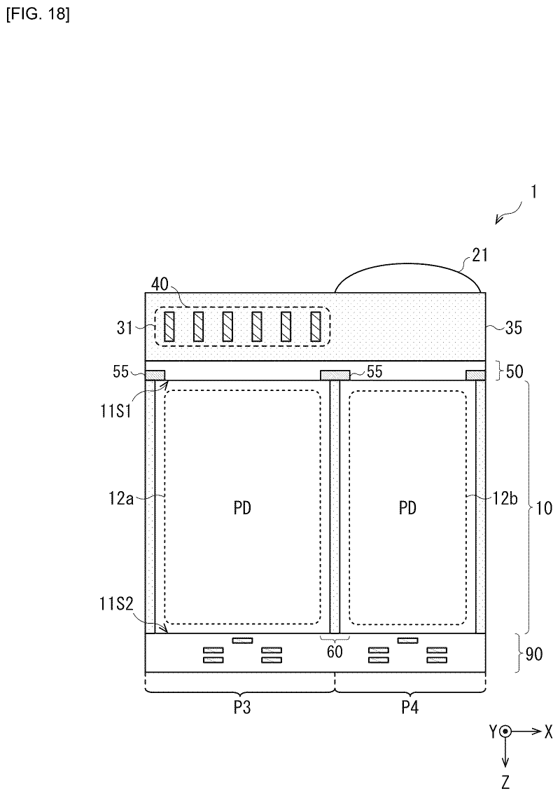

As illustrated in FIG. 17, a lens 21 may be disposed for the pixel P3 that is a large pixel and a light guide section 40 may be disposed for the pixel P4 that is a small pixel. Moreover, as illustrated in FIG. 18, the light guide section 40 may be disposed for the pixel P3 and the lens 21 may be disposed for the pixel P4.

In the present embodiment, it is possible to appropriately focus incident light at the pixel P3 that is a large pixel and at the pixel P4 that is a small pixel by the lens 21 and the light guide section 40. It is possible for the imaging device 1 to generate a pixel signal by the plurality of pixels P3 with high sensitivity and the plurality of pixels P4 with low sensitivity. This therefore makes it possible to enlarge a dynamic range.

### Workings and Effects

The optical detection device according to the present embodiment includes: a lens (the lens 21) where light is incident; a first photoelectric conversion element (for example, the photoelectric converter 12a) that photoelectrically converts light incident through the lens; a light guide member (the light guide section 40) that includes a plurality of structures; and a second photoelectric conversion element (for example, the photoelectric converter 12b) that photoelectrically converts light incident through the light guide member. The first photoelectric conversion element and the second photoelectric conversion element have mutually different sizes.

Provided in the optical detection device (the imaging device 1) according to the present embodiment are: pixels (for example, the pixels P3) that photoelectrically converts light incident through the lens 21; and pixels (for example, the pixels P4) that photoelectrically converts light incident through the light guide section 40. The photoelectric converter 12a and the photoelectric converter 12b have mutually different sizes. This therefore makes it possible to appropriately guide light at the pixel P3 and the pixel P4. It is possible to realize an optical detection device having favorable optical characteristics.

### 5. Application Example

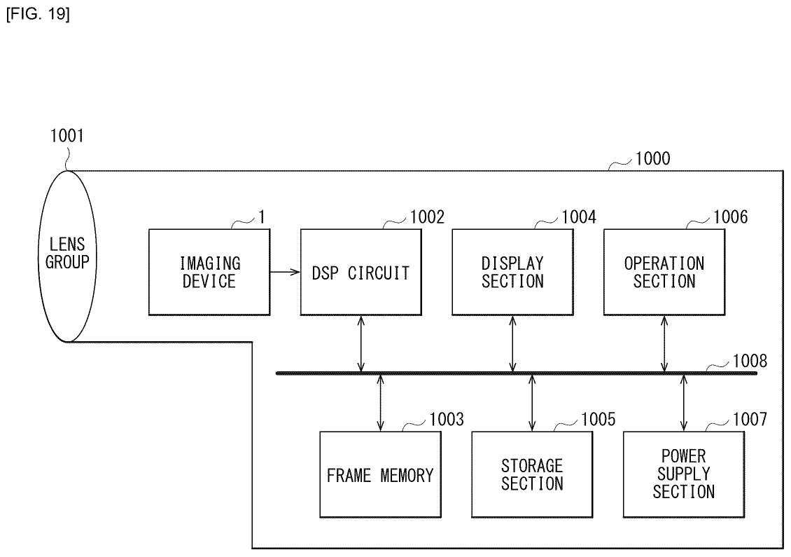

The imaging device 1, etc. described above is applicable to any types of electronic apparatuses, for example, a camera system such as a digital still camera or a video camera, a portable phone with an imaging function, that have an imaging function. FIG. 19 illustrates a schematic configuration of an electronic apparatus 1000.

The electronic apparatus 1000 has, for example, a lens group 1001, an imaging device 1, a digital signal processor section (DSP) circuit 1002, a frame memory 1003, a display 1004, a storage section 1005, an operation section 1006, and a power supply section 1007, which are mutually coupled together through a bus line 1008.

The lens group 1001 captures incident light (image light) from a subject and forms an image on an imaging surface of the imaging device 1. The imaging device 1 converts, into an electric signal in devices of pixels, an amount of the incident light whose image is formed on the imaging surface of the imaging device 1 by the lens group 1001, and supplies the signal as a pixel signal to the DSP circuit 1002.

The DSP circuit 1002 is a signal processor circuit that processes a signal supplied from the imaging device 1. The DSP circuit 1002 outputs image data obtained by processing the signal from the imaging device 1. The frame memory 1003 temporarily holds, in devices of frames, the image data processed by the DSP circuit 1002.

The display 1004 includes a panel type display device such as, for example, a liquid crystal panel or an organic electro luminescence (EL) panel, and records, on a recording medium such as a semiconductor memory or a hard disc, image data of a moving image or a still image formed in the solid-state imaging device 1.

The operation section 1006 outputs operation signals for various types of functions possessed by the electronic apparatus 1000 in accordance with operation performed by a user. The power supply section 1007 appropriately supplies, to supply targets, various types of powers serving as operating power sources of the DSP circuit 1002, the frame memory 1003, the display 1004, the storage section 1005, and the operation section 1006.

### 6. Practical Application Examples

### Practical Application Example to Mobile Body

The technology (present technology) according to the present disclosure is applicable to various products. For example, the technology according to the present disclosure may be achieved in the form of an apparatus to be mounted to a mobile body of any kind such as an automobile, an electric vehicle, a hybrid electric vehicle, a motorcycle, a bicycle, a personal mobility, an airplane, a drone, a vessel, and a robot.

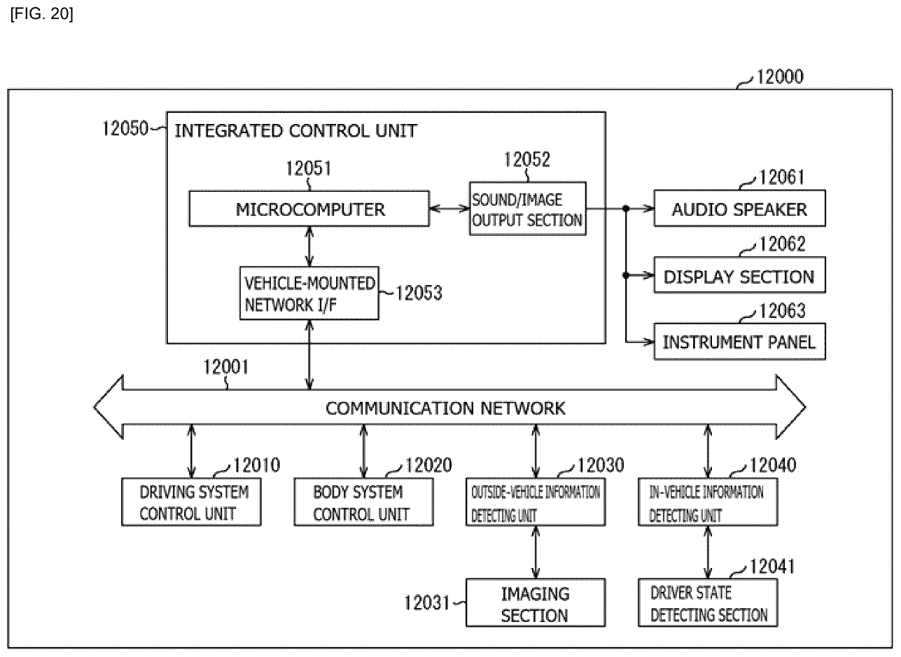

FIG. 20 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 20, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 20, an audio speaker 12061, a display section 12062, and an instrument panel 12063 are illustrated as the output device. The display section 12062 may, for example, include at least one of an on-board display and a head-up display.

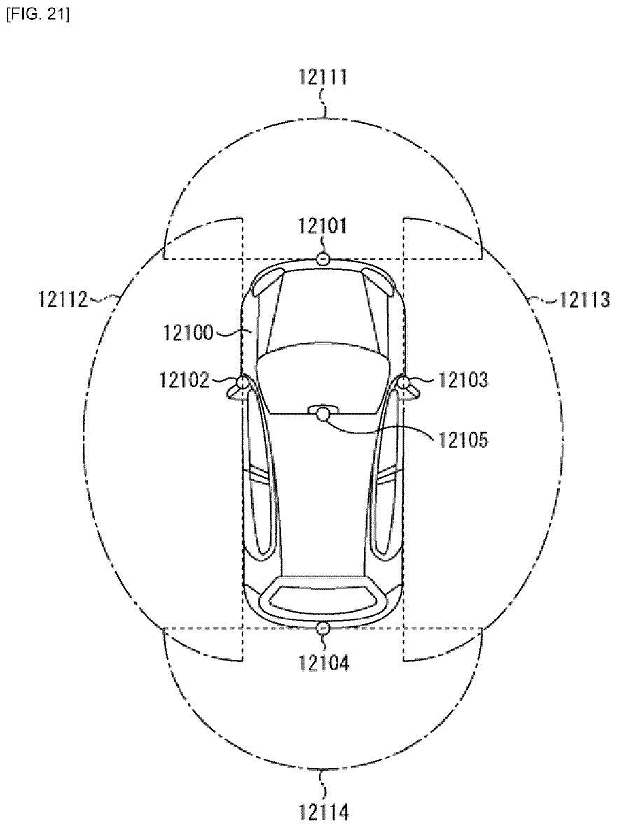

FIG. 21 is a diagram depicting an example of the installation position of the imaging section 12031.

In FIG. 21, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 21 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

The description has been given above of one example of the vehicle control system, to which the technology according to the present disclosure may be applied. The technology according to the present disclosure may be applied to the imaging section 12031 among the configurations described above. Specifically, for example, the imaging device 1 or the like is applicable to the imaging section 12031. The application of the technology according to the present disclosure to the imaging section 12031 makes it possible to obtain a high-definition shot image, and makes it possible to perform highly accurate control with use of the shot image in the mobile body control system.

### Practical Application Example to Endoscopic Surgery System

The technology according to the present disclosure (present technology) is applicable to various products. For example, the technology according to the present disclosure may be applied to an endoscopic surgery system.

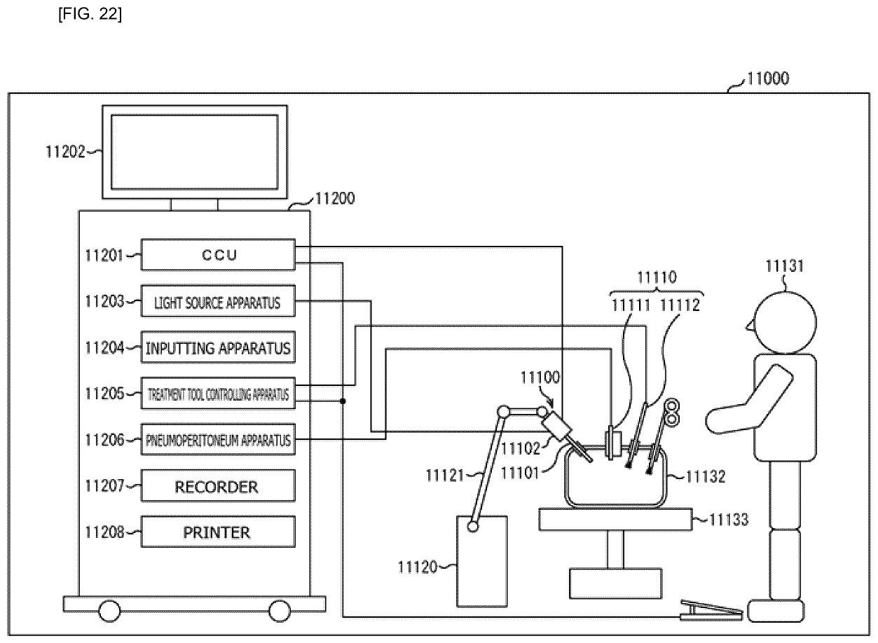

FIG. 22 is a view depicting an example of a schematic configuration of an endoscopic surgery system to which the technology according to an embodiment of the present disclosure (present technology) can be applied.

In FIG. 22, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

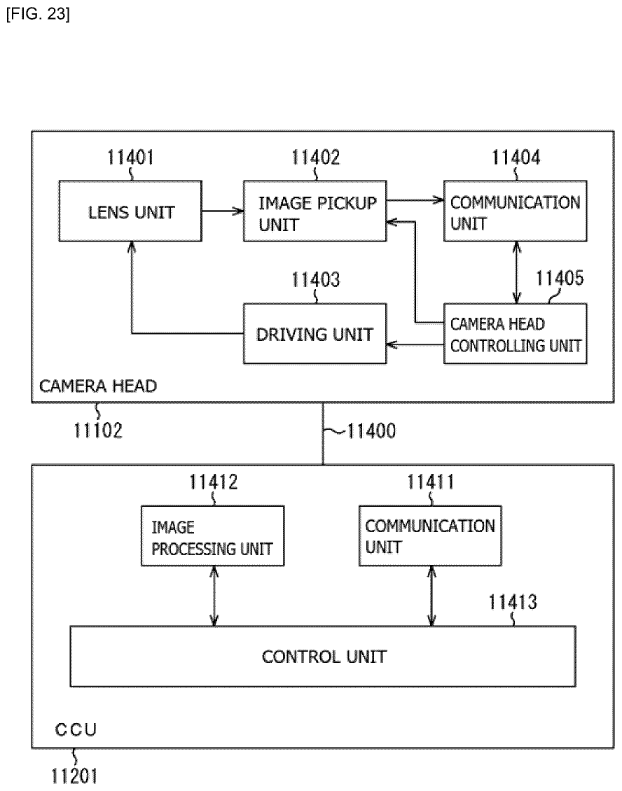

FIG. 23 is a block diagram depicting an example of a functional configuration of the camera head 11102 and the CCU 11201 depicted in FIG. 22.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

The description has been given above of one example of the endoscopic surgery system, to which the technology according to the present disclosure may be applied. The technology according to the present disclosure is suitably applicable to, for example, the image pickup unit 11402 provided in the camera head 11102 of the endoscope 11100 among the configurations described above. The application of the technology according to the present disclosure to the image pickup unit 11402 makes it possible to provide the image-pickup section 11402 with higher sensitivity, and makes it possible to provide the endoscope 11100 with high definition.

The present disclosure is described referring to the embodiments, the modification examples, and the application example, but the present technique is not limited to the embodiments, etc. described above and it is possible to make various modifications thereto. For example, the modification examples described above are described as modification examples of the embodiment described above, but it is possible to combine the configurations of the respective modification examples as appropriate. For example, the present disclosure is not limited to back-illuminated image sensors, but is also applicable to front-illuminated image sensors.

The aforementioned embodiments, etc. are described, referring to the imaging device as an example, but the optical detection device of the present disclosure may be, for example, any device that receives incident light and converts the light into electric charges. Signals outputted may be signals of image information or may be signals of distance measurement information. The optical detection device (imaging device) is applicable to image sensors, distance measurement sensors, etc.

The optical detection device according to the present disclosure is also applicable as a distance measurement sensor that is able to perform distance measurement using a time off flight (TOF) method. The optical detection device (imaging device) can also be applied as a sensor, for example, a sensor of an event driving type (called, for example, an event vision sensor (EVS), an event driven sensor (EDS), or a dynamic vision sensor (DVS)), that is able to detect an event.

By designing the first structures 31, the second structures 32, etc., the light guide section 40 as an optical element may be configured as a spectroscopic element (spectroscopic section) that is able to split light. In the aforementioned case, the light guide section 40 is also referred to as a splitter (color splitter). The optical detection device and the optical element (the light guide section 40) according to the present disclosure are applicable to various apparatuses.

The optical detection device according to one embodiment of the present disclosure includes: the first light guide member including the plurality of first structures and the plurality of second structures; and the first photoelectric conversion element that photoelectrically converts light incident through the first light guide member. The first structure and the second structure include mutually different materials. This therefore makes it possible to appropriately guide the incident light to the photelectric conversion element. It is possible to realize an optical detection device having favorable optical characteristics.

The optical detection device according to one embodiment of the present disclosure includes: the lens where light is incident; the first photoelectric conversion element that photoelectrically converts the light incident through the lens; the light guide member including the plurality of structures; and the second photoelectric conversion element that photoelectrically converts the light incident through the light guide member. This therefore makes it possible to appropriately guide the incident light in the optical detection device. It is possible to realize an optical detection device having favorable optical characteristics.

The optical element of the first embodiment of the present disclosure includes: the plurality of first structures; the plurality of second structures provided around the plurality of first structures; and the filling member provided between adjacent ones of the plurality of first structures and between adjacent ones of the plurality of second structures. The first structure and the second structure include the mutually different materials. This therefore makes it possible to appropriately guide the incident light. It is possible to realize an optical element having favorable optical characteristics.

Note that the effects described in the description are just illustrative and the effects are not limited to those described, and other effects may be provided. Moreover, it is possible to have configurations as described below.
(1)

An optical detection device including:
a first light guide member including a plurality of first structures and a plurality of second structures; and
a first photoelectric conversion element that photoelectrically converts light incident through the first light guide member, in which
the first structure and the second structure include mutually different materials.
(2)

The optical detection device according to (1), including a filling member provided around the first structure, in which
the first structure has a higher refractive index than the filling member.
(3)

The optical detection device according to (1) or (2), in which the second structure has a lower refractive index than the first structure.
(4)

The optical detection device according to anu one of (1) to (3), including a filling member provided around the second structure, in which
the second structure has a lower refractive index than the filling member.
(5)

The optical detection device according to any one of (1) to (4), in which the second structure is configured using a void.
(6)

The optical detection device according to any one of (1) to (5), including a plurality of pixels including a first pixel having the first photoelectric conversion element, in which
at least a part of the second structures is provided at a border between adjacent ones of the plurality of pixels.
(7)

The optical detection device according to any one of (1) to (6), including a plurality of pixels including a first pixel having the first photoelectric conversion element, in which
the second structures are provided around the first structure and at a border between adjacent ones of the plurality of pixels.
(8)

The optical detection device according to any one of (1) to (7), including a first antireflection film provided on the first structure, in which
the first antireflection film has a lower refractive index than the first structure.
(9)

The optical detection device according to any one of (1) to (8), including a second antireflection film provided on the second structure, in which
the second antireflection film has a refractive index different from a refractive index of the second structure.
(10)

The optical detection device according to any one of (1) to (9), in which the first structure and the second structure each have a size equal to or less than a wavelength range of infrared light or equal to or less than a wavelength range of visible light.
(11)

The optical detection device according to any one of (1) to (10), including a pixel array provided with a plurality of pixels including a first pixel having the first photoelectric conversion element and a second pixel having a second photoelectric conversion element, in which
the second pixel is located at a position closer to a center of the pixel array than the first pixel,
the second pixel has a second light guide member including a plurality of third structures, and
the second photoelectric conversion element photoelectrically converts light incident through a second guide member.
(12)

The optical detection device according to (11), in which t the first structure and the third structure include mutually different materials.
(13)

The optical detection device according to (11) or (12), in which the first structure has a higher refractive index than the third structure.
(14)

An optical detection device including:
a lens where light is incident;
a first photoelectric conversion element that photoelectrically converts the light incident through the lens;
a light guide member including a plurality of structures; and
a second photoelectric conversion element that photoelectrically converts light incident through the light guide member.
(15)

The optical detection device according to (14), including:
a first pixel including the lens, and the first photoelectric conversion element that photoelectrically converts visible light incident through the lens; and
a second pixel including the light guide member, and the second photoelectric conversion element that photoelectrically converts infrared light incident through the light guide member.
(16)

The optical detection device according to (14) or (15), including:
a first pixel including the lens, and the first photoelectric conversion element that photoelectrically converts infrared light incident through the lens; and
a second pixel including the light guide member, and the second photoelectric conversion element that photoelectrically converts visible light incident through the light guide member.
(17)

The optical detection device according to any one of (14) to (16), in which the first photoelectric conversion element and the second photoelectric conversion element have mutually different sizes.

### (18)

The optical detection device according to any one of (14) to (17), in which the lens, the first photoelectric conversion element, the light guide member, and the second photoelectric conversion element are provided from a light incidence side.
(19)

An optical element including:
a plurality of first structures;
a plurality of second structures provided around the plurality of first structures; and
a filling member provided between adjacent ones of the plurality of first structures and between adjacent ones of the plurality of second structures, in which
the first structure and the second structure include mutually different materials.
(20)

An electronic apparatus including:
an optical system; and
an optical detection device that receives light transmitted through the optical system, in which the optical detection device includes
a first light guide member including a plurality of first structures and a plurality of second structures, and
a first photoelectric conversion element that photoelectrically converts light incident through the first light guide member, and
the first structure and the second structure include mutually different materials.

The present application claims the benefit of Japanese Priority Patent Application JP2023-015393 filed with the Japan Patent Office on Feb. 3, 2023, the entire contents of which are incorporated herein by reference.

It should be understood by those skilled in the art that various modifications, combinations, sub-combinations and alterations may occur depending on design requirements and other factors insofar as they are within the scope of the appended claims or the equivalents thereof.

1. An optical detection device comprising:
a first light guide member including a plurality of first structures and a plurality of second structures; and
a first photoelectric conversion element that photoelectrically converts light incident through the first light guide member, wherein
the first structure and the second structure include mutually different materials.

2. The optical detection device according to claim 1, comprising a filling member provided around the first structure, wherein
the first structure has a higher refractive index than the filling member.

3. The optical detection device according to claim 1, wherein the second structure has a lower refractive index than the first structure.

4. The optical detection device according to claim 1, comprising a filling member provided around the second structure, wherein
the second structure has a lower refractive index than the filling member.

5. The optical detection device according to claim 1, wherein the second structure is configured using a void.

6. The optical detection device according to claim 5, comprising a plurality of pixels including a first pixel having the first photoelectric conversion element, wherein
at least a part of the second structures is provided at a border between adjacent ones of the plurality of pixels.

7. The optical detection device according to claim 5, comprising a plurality of pixels including a first pixel having the first photoelectric conversion element, wherein
the second structures are provided around the first structure and at a border between adjacent ones of the plurality of pixels.

8. The optical detection device according to claim 1, comprising a first antireflection film provided on the first structure, wherein
the first antireflection film has a lower refractive index than the first structure.

9. The optical detection device according to claim 1, comprising a second antireflection film provided on the second structure, wherein
the second antireflection film has a refractive index different from a refractive index of the second structure.

10. The optical detection device according to claim 1, wherein the first structure and the second structure each have a size equal to or less than a wavelength range of infrared light or equal to or less than a wavelength range of visible light.

11. The optical detection device according to claim 1, comprising a pixel array provided with a plurality of pixels including a first pixel having the first photoelectric conversion element and a second pixel having a second photoelectric conversion element, wherein
the second pixel is located at a position closer to a center of the pixel array than the first pixel,
the second pixel has a second light guide member including a plurality of third structures, and
the second photoelectric conversion element photoelectrically converts light incident through a second guide member.

12. The optical detection device according to claim 11, wherein the first structure and the third structure include mutually different materials.

13. The optical detection device according to claim 11, wherein the first structure has a higher refractive index than the third structure.

14. An optical detection device comprising:
a lens where light is incident;
a first photoelectric conversion element that photoelectrically converts the light incident through the lens;
a light guide member including a plurality of structures; and
a second photoelectric conversion element that photoelectrically converts light incident through the light guide member.

15. The optical detection device according to claim 14, comprising:
a first pixel including the lens, and the first photoelectric conversion element that photoelectrically converts visible light incident through the lens; and
a second pixel including the light guide member, and the second photoelectric conversion element that photoelectrically converts infrared light incident through the light guide member.

16. The optical detection device according to claim 14, comprising:
a first pixel including the lens, and the first photoelectric conversion element that photoelectrically converts infrared light incident through the lens; and
a second pixel including the light guide member, and the second photoelectric conversion element that photoelectrically converts visible light incident through the light guide member.

17. The optical detection device according to claim 14, wherein the first photoelectric conversion element and the second photoelectric conversion element have mutually different sizes.

18. The optical detection device according to claim 14, wherein the lens, the first photoelectric conversion element, the light guide member, and the second photoelectric conversion element are provided from a light incidence side.

19. An optical element comprising:
a plurality of first structures;
a plurality of second structures provided around the plurality of first structures; and
a filling member provided between adjacent ones of the plurality of first structures and between adjacent ones of the plurality of second structures, wherein
the first structure and the second structure include mutually different materials.

20. An electronic apparatus comprising:
an optical system; and
an optical detection device that receives light transmitted through the optical system, wherein
the optical detection device includes
a first light guide member including a plurality of first structures and a plurality of second structures, and
a first photoelectric conversion element that photoelectrically converts light incident through the first light guide member, and
the first structure and the second structure include mutually different materials.
